(19) United States
(12) Patent Application Publication
(10) Pub. No.: US 2007/0218204 A1
(43) Pub. Date: Sep. 20, 2007

(54) APPARATUS AND PROCESS FOR SURFACE TREATMENT OF SUBSTRATE USING AN ACTIVATED REACTIVE GAS

(76) Inventors: Diwakar Garg, Emmaus, PA (US); Steven Arnold Krouse, Tamaqua, PA (US); Eric Anthony Robertson III, Easton, PA (US); Pingping Ma, Orefield, PA (US)

Correspondence Address: AIR PRODUCTS AND CHEMICALS, INC.;PATENT DEPARTMENT, 7201 HAMILTON BOULEVARD, ALLENTOWN, PA, 181951501, US

(21) Appl. No.: 11/689,074

(22) Filed: Mar. 21, 2007

Related U.S. Application Data
(63) Continuation-in-part of application No. 11/080,330, filed on Mar. 15, 2005.
(60) Provisional application No. 60/612,060, filed on Sep. 21, 2004.

(30) Foreign Application Priority Data
Sep. 20, 2005 (US) PCT/US05/33370
Sep. 13, 2006 (US) PCT/US06/35962

(51) Int. Cl. C23C 16/00

(52) U.S. Cl. 427/255.11; 118/723 R; 118/729; 427/248.1

(57) ABSTRACT

An apparatus for treatment a substrate with an activated reactive gas which includes a processing chamber, an exhaust manifold, a conveyor adapted to sequentially introduce into the processing chamber untreated portions of the substrate for said treatment and to sequentially remove from the processing chamber treated portions of the substrate, wherein the length of the substrate exceeds a dimension of the inner volume of the processing chamber, a distribution conduit disposed in the processing chamber, wherein the length of the distribution conduit is approximately equal to the width of the substrate, and wherein the distribution conduit has a number (N) of openings, each opening has a cross sectional area (Aₒ), a cross sectional area of the distribution conduit (A_{c}), and wherein a maximum cross-sectional area (N*Aₒ) of the openings can be determined by the following expression: 1.0*A_{c}>N*Aₒ≧0.1*A_{c}.

### CROSS-REFERENCE TO RELATED APPLICATIONS

This application is a continuation-in-part of International Application Serial No. PCT/US05/33370 filed Sep. 20, 2005 which claims benefit of Ser. No. 11/080,330, International Application Serial No. PCT/US06/035962 filed Sep. 13, 2006, and a continuation-in-part of U.S. application Ser. No. 11/080,330 filed on Mar. 15, 2005, which are incorporated herein in their entireties.

### BACKGROUND OF THE INVENTION

The present invention relates to an apparatus and process for treatment of a substrate with an activated reactive gas.

Surface treatment of relatively wide (e.g., greater than 1 foot wide or 3 feet wide or greater), long (e.g., greater than 2 feet long or 4 feet long or greater) and/or large surface areas (e.g., 2 square feet or greater or 12 square feet or greater) of a variety of substrates including glass, metals, semi-metals, polymers, ceramics and plastics, as well as substrates such as glass, metals, semi-metals, polymers, ceramics and plastics and deposited with a wide variety of coatings, is becoming increasingly important to a variety of industries. In this connection, proposals have been made to treat surfaces of polymers, plastics and metals, semi-metals and ceramics to improve their adhesion and/or bonding to other materials; polymers and plastics to change their gas and liquid permeation properties; polymers, plastics, glass and ceramics to impart them hydrophilic or hydrophobic properties; coated and uncoated polymers, plastics, metals, semi-metals, ceramics and glass to remove undesirable surface contaminants such as moisture, oil, etc., and/or uncoated and coated polymers, plastics, glass and ceramics to change their optical characteristics such as light absorption, transmission, reflection and scattering.

A well known method for removing unwanted materials such as silicon or silicon oxide from a processing chamber such as, for example, a chemical vapor deposition (CVD) reactor or plasma enhanced chemical vapor deposition (PECVD) reactor for semiconductor manufacturing, is to introduce a reactive gas into the chamber through a shower head and activating the reactive gas by generating a plasma within the chamber to etch away the unwanted materials. The purpose of the shower head is to distribute the reactive gases over the exposed area of the substrate. Such a process is generally called in situ plasma activation and cleaning of the substrate or the deposition chamber or “in situ plasma cleaning”.

Another well known method of removing unwanted materials such as silicon or silicon oxide from a processing chamber, such as a CVD reactor or a PECVD reactor for semiconductor manufacturing or flat panel display, is to activate the reactive gas in a location outside of the reactor by plasma and introducing the activated species (i.e., ions, free radicals, electrons, particles, etc.) into the chamber through a shower head to etch away the unwanted materials. Such a method is referred to herein as “remote plasma cleaning”. Remote plasma cleaning may be also used for cleaning deposition residues from the walls and/or fixtures of the processing chamber. In these applications, uniformity of gas distribution is not important and the substrate is not present in the chamber.

A lesser known method of removing unwanted materials such as silicon or silicon oxide from a processing chamber is to introduce a reactive gas into a top portion of the chamber that is isolated from the main portion of the processing chamber through the distributor plate, activate the reactive gas in situ in the top portion of the reactor chamber, and then introduce the activated species into the main portion through the distributor plate. Such a method is referred to herein as a “modified in situ plasma cleaning.”

U.S. Pat. Nos. 6,245,396 B1 and 6,892,669 B2 disclose a process for in-situ plasma enhanced deposition and cleaning of a CVD reactor. The substrate and/or chamber are cleaned by introducing reactive gas through a distributor plate or shower head and activating the reactive gas by generating an in-situ plasma. It is, however, limited to cleaning small area substrates because of difficulty in maintaining plasma uniformity on large area substrates. Consequently, it may not be suitable for cleaning or treating surfaces of large area substrates.

U.S. Pat. No. 4,792,378 describes another version of the in-situ plasma enhanced deposition and cleaning of a CVD reactor. A flat gas deflection disk is placed just above the shower head to obtain a better distribution of reactive gas into the main chamber.

U.S. Pat. Nos. 6,299,725 B1, 6,387,816 B2, 6,617,256 B2, 6,833,049 B2, 2002/0026983 A1, and WO 99/00532 disclose a modified in-situ plasma method for cleaning of a CVD reactor. The reactive gas is activated with plasma at the top portion of the chamber and the activated reactive gas is introduced into the main chamber through a shower head to clean the chamber. A portion of unactivated reactive gas is also introduced directly into the chamber through a secondary distribution ring to aid in cleaning. No information is provided in the foregoing references about the design of the secondary distribution ring to distribute reactive gas uniformly into the chamber. In any case, the in-situ plasma cleaning method is limited to cleaning small area substrates because of difficulty in maintaining plasma uniformity on large area substrates. Consequently, it may not be suitable for cleaning or treating surfaces of large area substrates.

U.S. Pat. No. 5,614,026, U.S. Pat. No. 5,788,778 and EP 0980092 B1 describe a remote plasma cleaning method in which remotely activated reactive gas stream is introduced into the cleaning chamber via a shower head.

U.S. 2004/0065256 A1 describes a gas distribution channel to introduce gas into a chemical vapor deposition chamber. The published application mentions that the cross-section of the gas distribution channel is 10 to 100 times greater than the gas injection port, but fails to mention anything about the number of ports required to provide uniform distribution of the gas within the deposition chamber.

EP 0709875 A1 and WO 99/65057 disclose a ring shaped design of a distributor for uniformly distributing reactive gas into the deposition chamber.

U.S. 2004/0025786 A1 discloses a dual gas introduction system with a buffer chamber in between to introduce reactive gas uniformly along a stacking direction of the substrates. The dual gas introduction system may significantly increase the contact of reactive gas with the metal surface area within the gas distribution system that is extremely detrimental to keeping a plasma activated reactive gas in activated form. Consequently, this design of a gas distribution system is not suitable for introducing a plasma activated reactive gas into a processing chamber.

EP 1,276,031 A1 discloses a pipe within a pipe system to provide uniform flow of gas through a series of apertures. The design of the inner pipe or manifold requires that the ratio of total opening area to the manifold cross-sectional area not exceed unity. This design requirement cannot be used to provide uniform gas distribution through a manifold. Further, a pipe in a pipe design cannot be used to introduce plasma activated reactive gas into a chamber because such a system is extremely detrimental to keeping plasma activated reactive gas in activated form. Consequently, this design of a gas distribution system is not suitable for introducing plasma activated reactive gas into a processing chamber.

The above in-situ plasma, modified in-situ plasma and remote plasma techniques for removing unwanted deposits from the substrates or walls of a CVD reactor with plasma activated reactive gas—where the reactive gas is activated either with an in-situ plasma source or by using a remote plasma source—can also be used to treat surfaces of various substrates for the purposes described herein. For example, surfaces of these materials can be treated with appropriate activated reactive gas to roughen or smooth the uncoated or coated substrate surfaces, to selectively etch or remove materials or coatings, oxidize or reduce materials present on the surface, and to improve roughness or smoothness of the uncoated and coated substrate surfaces by selectively removing or etching high points and/or low points. These surface treatment techniques are known to be effective in changing one or more optical characteristics such as light absorption, transmission, reflection and/or scattering of uncoated or coated substrates.

Although the use of an in-situ plasma activated reactive gas system is effective in treating materials, treatment with an in-situ activated reactive gas system is limited to small surface areas (e.g., substrates having a diameter ranging from 4 to 12 inches for microelectronic applications or dimensions less than 1 foot in width, less than 2 feet in length, and or an exposed surface area of less than 2 square feet for flat panel display applications), surfaces that are not prone to damage caused by ion bombardment, and/or surfaces that require crude surface modification. The majority of the aforementioned processes and treatments are used to deposit rather than etch or treat the surface of a substrate. Furthermore, it has been difficult to implement in-situ plasma activation of a reactive gas system for treating wide, long, and/or large surface areas of materials precisely, uniformly and reproducibly. Similarly, treatment with a remote plasma activated reactive gas system has, thus far, been limited to small surface areas.

It has been difficult to implement a remote activated reactive gas treatment system to modify or treat materials having wide and/or long surface areas precisely, uniformly, and reproducibly. The problems are believed to be related to distribution of activated reactive gas uniformly in the processing chamber and loss in activity of the activated reactive gas due to recombination of the activated species present within the activated reactive gas. Therefore, there is a need to develop a reactive gas treatment system that is suitable for treating, modifying or etching wide and/or long areas of a substrate, avoids damage to the substrate by ion bombardment, distributes activated reactive gas uniformly over the wide and/or long surface areas of substrates without significantly losing treatment effectiveness due to recombination of activated species present in the activated reactive gas.

### BRIEF SUMMARY OF THE INVENTION

Accordingly, a first aspect of the invention comprises an apparatus for treatment of at least a portion of a surface of a substrate with an activated reactive gas, the apparatus comprising:
(a) a processing chamber having an inner volume and being in communication with the substrate;
(b) an exhaust manifold disposed in the processing chamber;
(c) a conveyor in communication with the processing chamber and the substrate, the conveyor being adapted to sequentially introduce into the processing chamber untreated portions of the substrate for said treatment and to sequentially remove from the processing chamber treated portions of the substrate;
(d) the substrate in communication with the processing chamber and the conveyor, the substrate having a length and a width, wherein the length of the substrate exceeds a dimension of the inner volume of the processing chamber;
(e) a distribution conduit disposed in the processing chamber, the distribution conduit having a length, an entry port for the process gas or the activated reactive gas, and a plurality of openings for directing a process gas or the activated reactive gas into the inner volume, wherein the length of the distribution conduit is approximately equal to the width of the substrate, and wherein the distribution conduit has a number (N) of openings, each opening has a cross sectional area (Aₒ), and a cross sectional area of the distribution conduit (A_{c}), and wherein a maximum cross-sectional area (N*Aₒ) of the openings can be determined by the following expression:
   1.0A_{c}>N*Aₒ≧0.1*A_{c};
(f) a supply of a process gas; and
(g) an energy source for activating the process gas in fluid communication with the processing chamber and the distribution conduit.

A second aspect of the invention comprises an apparatus for treatment of at least a portion of a surface of a substrate with an activated reactive gas, the apparatus comprising:
(a) a processing chamber having an inner volume and being in communication with the substrate;
(b) an exhaust manifold disposed in the processing chamber;
(c) a conveyor in communication with the processing chamber and the substrate, the conveyor being adapted to sequentially introduce into the processing chamber untreated portions of the substrate for said treatment and to sequentially remove from the processing chamber treated portions of the substrate;
(d) the substrate in communication with the processing chamber and the conveyor, the substrate having a length and a width, wherein the length of the substrate exceeds a dimension of the inner volume of the processing chamber;
(e) a distribution conduit disposed in the processing chamber, the distribution conduit having a length, an entry port for the process gas or the activated reactive gas, and a plurality of openings for directing a process gas or the activated reactive gas into the inner volume, wherein the length of the distribution conduit is approximately equal to the width of the substrate, and wherein each opening of the distribution conduit has a sidewall chamfered at an angle (α), each opening is spaced apart from another opening by a distance (x), and the distribution conduit is disposed at a distance (y) from the substrate presented for said treatment such that
   x/(2*tan α)≦y;
(f) a supply of a process gas; and
(g) an energy source for activating the process gas in fluid communication with the processing chamber and the distribution conduit.

A third aspect of the invention comprises an apparatus for treatment of a substrate with an activated reactive gas (see, for example, FIG. 7), the apparatus comprising:
(a) a processing chamber having an inner volume and a side wall and optionally a plate, the plate being disposed between the side wall of the processing chamber and the substrate;
(b) an exhaust manifold disposed in the processing chamber;
the substrate disposed in the processing chamber in front of the side wall or the plate, the substrate having a length and a width, and wherein a distance between the substrate and the side wall or the substrate and the plate is selected to allow a uniform contact of the activated reactive gas with a surface of the substrate;
(c) a distribution conduit disposed in the processing chamber in at least one of the following configurations: (i) between the substrate and the side wall of the processing chamber or (ii) between the substrate and the plate, provided that the distribution conduit is disposed substantially parallel to the surface of the substrate, the distribution conduit having a length, an entry port for the process gas or the activated reactive gas and a plurality of openings for directing a process gas or the activated reactive gas into the inner volume, wherein said length is approximately equal to at least one of the length and the width of the substrate, and wherein the openings of the distribution conduit are adapted to dispense the process gas or the activated reactive gas in a direction substantially parallel to the surface of the substrate during said treatment;
(d) a supply of a process gas; and
(e) an energy source for activating the process gas in fluid communication with the processing chamber and the distribution conduit.

A fourth aspect of the invention comprises a process for treatment of at least a portion of a surface of a substrate with an activated reactive gas, the process includes:
(1) providing a processing chamber, the processing chamber having an inner volume and an exhaust manifold disposed in the processing chamber;
(2) providing a conveyor in communication with the processing chamber and the substrate;
(3) placing the substrate having a length and a width in communication with the processing chamber and the conveyor, wherein the length of the substrate exceeds a dimension of the inner volume of the processing chamber;
(4) providing a distribution conduit inside the processing chamber, the distribution conduit having a length and a plurality of openings, wherein the length of the distribution conduit is approximately equal to the width of the substrate, and wherein the distribution conduit has a number (N) of openings, each opening has a cross sectional area (Aₒ), and a cross sectional area of the distribution conduit (A_{c}), and wherein a maximum cross-sectional area (N*Aₒ) of the openings can be determined by the following expression:
   1.0*A_{c}>N*Aₒ≧0.1*A_{c};
(5) providing a supply of a process gas, the process gas comprising a reactive gas and optionally an additive gas;
(6) providing an energy source in fluid communication with the processing chamber and the distribution conduit;
(7) activating the process gas with the energy source to generate the activated reactive gas;
(8) delivering the process gas or the activated reactive gas to the distribution conduit through the entry port;
(9) removing a spent process gas via the exhaust manifold;
(10) directing the process gas or the activated reactive gas from the distribution conduit onto the at least the portion of the surface of the substrate through the plurality of openings such that the process gas or the activated reactive gas is delivered uniformly along the width of the substrate;
(11) sequentially presenting untreated portions of the substrate for said treatment in the processing chamber and sequentially removing from the processing chamber treated portions of the substrate; and
(12) contacting the untreated portions of the substrate with the activated reactive gas and thereby providing said treatment.

A fifth aspect of the invention comprises a process for treatment of at least a portion of a surface of a substrate with an activated reactive gas, the process includes:
(1) providing a processing chamber, the processing chamber having an inner volume and an exhaust manifold disposed in the processing chamber;
(2) providing a conveyor in communication with the processing chamber and the substrate;
(3) placing the substrate having a length and a width in communication with the processing chamber and the conveyor, wherein the length of the substrate exceeds a dimension of the inner volume of the processing chamber;
(4) providing a distribution conduit inside the processing chamber, the distribution conduit having a length, an entry port for the process gas or the activated reactive gas, and a plurality of openings for directing a process gas or the activated reactive gas into the inner volume, wherein the length of the distribution conduit is approximately equal to the width of the substrate, and wherein each opening of the distribution conduit has a sidewall chamfered at an angle (α), each opening is spaced apart from another opening by a distance (x), and the distribution conduit is disposed at a distance (y) from the substrate presented for said treatment such that
   x/(2*tan α)≦y;
(5) providing a supply of a process gas, the process gas comprising a reactive gas and optionally an additive gas;
(6) providing an energy source in fluid communication with the processing chamber and the distribution conduit;
(7) activating the process gas with the energy source to generate the activated reactive gas;
(8) delivering the process gas or the activated reactive gas to the distribution conduit through the entry port;
(9) removing a spent process gas via the exhaust manifold;
(10) directing the process gas or the activated reactive gas from the distribution conduit onto the at least the portion of the surface of the substrate through the plurality of openings such that the process gas or the activated reactive gas is delivered uniformly along the width of the substrate;
(11) sequentially presenting untreated portions of the substrate for said treatment in the processing chamber and sequentially removing from the processing chamber treated portions of the substrate; and
(12) contacting the untreated portions of the substrate with the activated reactive gas and thereby providing said treatment.

A sixth aspect of the invention comprises a process for treatment of a substrate with an activated reactive gas (see, for example, FIG. 7), the process includes:
(1) providing a processing chamber, the processing chamber having an inner volume, a side wall, an exhaust manifold and optionally a plate, the plate being disposed between the side wall of the processing chamber and the substrate;
(2) placing the substrate inside the processing chamber and in front of the side wall or the plate such that a distance between the substrate and the side wall or the substrate and the plate is selected to allow a uniform contact of the activated reactive gas with a surface of the substrate, the substrate having a length and a width;
(3) providing a distribution conduit inside the processing chamber, wherein the distribution conduit is provided in at least one of the following configurations: (i) between the substrate and the side wall of the processing chamber or (ii) between the substrate and the plate, such that the distribution conduit is disposed substantially parallel to the surface of the substrate, the distribution conduit having a length, an entry port for the process gas or the activated reactive gas and a plurality of openings for directing a process gas or the activated reactive gas into the inner volume, wherein said length is approximately equal to at least one of the length and the width of the substrate;
(4) providing a supply of a process gas, the process gas comprising a reactive gas and optionally an additive gas;
(5) providing an energy source for activating the process gas in fluid communication with the processing chamber and the distribution conduit;
activating the process gas with the energy source to generate the activated reactive gas;
(6) delivering the process gas or the activated reactive gas to the distribution conduit through the entry port;
(7) removing a spent process gas via the exhaust manifold;
(8) directing the process gas or the activated reactive gas from the distribution conduit onto the surface of the substrate through the openings of the distribution conduit such that the process gas is delivered uniformly along the width or the length of the substrate in a direction substantially parallel to the surface of the substrate; and
(9) contacting the surface of the substrate with the activated reactive gas and thereby providing said treatment.

### BRIEF DESCRIPTION OF SEVERAL VIEWS OF THE DRAWINGS

FIG. 1 provides a top view of one embodiment of the apparatus described herein that is used to treat the wide and/or long surface of a substrate wherein the substrate is treated using a remotely activated process gas.

FIG. 2 provides a side view of the apparatus of FIG. 1 taken along cross-sectional line A-A′.

FIG. 3 provides a cross-sectional view of one embodiment of the distribution conduit of FIG. 1.

FIG. 4 provides a detailed view of the one embodiment of an opening within the distribution conduit shown in FIG. 3.

FIG. 5 provides a top view of one embodiment of the distribution conduit of FIG. 1 taken along cross-sectional line B-B′.

FIG. 6 provides a side view of another embodiment of the apparatus described herein wherein the substrate is treated using an in situ activated process gas.

FIG. 7 provides an isometric view of yet another embodiment of the apparatus described herein wherein the substrate is contacted with a remote activated process gas that flows substantially parallel to the surface of the substrate being treated.

FIG. 8a provides an isometric view of the flow pattern for a comparative apparatus wherein the substrate is contacted with a plasma activated process gas through a singular inlet and singular exhaust manifold outlet.

FIG. 8b provides an isometric view of the flow pattern for a comparative apparatus wherein the substrate is contacted with a plasma activated process gas through a distribution conduit having 18 rectangular openings and a singular exhaust manifold outlet.

FIG. 8c provides an isometric view of the flow pattern for a comparative apparatus wherein the substrate is contacted with a plasma activated process gas through a distribution conduit having 18 rectangular openings which are slightly smaller in size than that depicted in FIG. 8b and a singular exhaust manifold outlet.

FIG. 8d provides an isometric view of the flow pattern for a comparative apparatus wherein the substrate is contacted with a plasma activated process gas through a distribution conduit having 18 rectangular openings which are slightly smaller in size than that depicted in FIG. 8b and an exhaust manifold outlet that has an opening that is slightly larger than the openings in FIG. 8c.

FIG. 9 provides an isometric view of yet another embodiment of the apparatus wherein the activated process gas is split and the substrate is contacted with a remote activated process gas that flows substantially parallel to the surface of the substrate being treated. The activated process gas is introduced in the chamber using a T-shaped distributor within the distribution system.

FIG. 10a provides an isometric view of the flow pattern for a comparative apparatus wherein the activated process gas is split and wherein the substrate is contacted with a plasma activated process gas through a distribution conduit having multiple rectangular openings.

FIG. 10b provides an isometric view of the flow pattern for a comparative apparatus wherein the activated process gas is split and wherein the substrate is contacted with a plasma activated process gas through a distribution conduit having more multiple rectangular openings than that FIG. 10a. Also, the size of each opening is larger as compared to the openings in FIG. 10a.

### DETAILED DESCRIPTION OF THE INVENTION

The apparatus and process described herein treat relatively large surface areas of a substrate, which is wide (e.g., greater than 1 foot wide or 3 feet wide or greater or 4 feet wide or greater or ranging from 4 feet to 15 feet wide), long (e.g., greater than 2 feet long, 4 feet long or greater, or ranging from 5 to 25 feet long), and/or has a relatively large exposed surface area (e.g., 2 square feet or greater or 12 square feet or greater or ranging from 12 square feet to 375 square feet) precisely, uniformly and reproducibly by contacting at least a portion of surface area of the substrate with an activated reactive gas, preferably a plasma activated reactive gas.

The term “activated reactive gas” describes at least a portion of a process gas comprising one or more reactive gases that is activated by exposure to one or more energy sources comprising a plasma source such as a remote plasma energy source, an in situ plasma source, and mixtures thereof, or more preferably a remote plasma energy source, to provide active species, i.e., atoms, radicals, electrons, ions, etc. At least one of the characteristics of the treated surface is altered by contact with the activated reactive gas. The residual activated reactive gas and/or by-product of the reaction such as volatile products between the surface and the activated reactive gas may be readily removed through the exhaust manifold and withdrawn from the processing chamber by the vacuum pump of the processing chamber or other means. In certain embodiments, the product of the reaction between at least a portion of the substrate surface and the activated reactive gas may be a species having a relatively higher volatility. In these embodiments, the term “volatile products”, as used herein, relates to reaction products and by-products of the reaction between the treated surface to be removed and the activated species of a reactive gas comprising one or more gases.

The terms “surface treatment” or “treatment” as used herein describe a process wherein at least one characteristic of the surface is changed during and/or after the process is completed. The term “surface treatment” or “treatment” shall not include layer depositions, i.e., the deposition of a substance as a layer onto the surface of the substrate. Specifically the terms shall not include any type of chemical vapor deposition (CVD) processes for depositing a layer or a film. The terms shall not exclude the implantation of individual chemical species (e.g., fluorine, chlorine, C. N, O) into an existing surface layer. Examples of surface treatments described herein include, but are not limited to, surface smoothening, surface roughening, surface reduction, surface oxidation, surface nitriding, surface carburization, surface carbonitriding, surface fluorination and/or etching processes. Depending upon the material of the substrate (or the material of the coating disposed upon the substrate), the surface treatment apparatus and process described herein may result in the substrate exhibiting one or more of the following characteristics: improved adhesion and/or bonding to other materials; altered gas and liquid permeation properties; altered hydrophilic or hydrophobic properties; a surface substantially free of undesirable surface contaminants such as moisture, oil, etc.; and/or altered optical characteristics such as light absorption, transmission, reflection and scattering.

The term “activated reactive gas” and the term “reactive process gas” are used interchangeably herein. The activated reactive gas is distributed inside the processing chamber using a distribution system that enables sufficient exposure of the wide, long, and/or large surface areas to the activated reactive gas and minimizes the loss in effectiveness of the activated species contained within the activated reactive gas due to recombination of activated species. It is believed that the distribution system fulfills at least two conflicting criteria: providing uniform gas distribution to the substrate surface while maximizing the amount of activated reactive gas reaching the substrate surface. The latter may be achieved by limiting the amount of contact of the activated reactive gas with the distribution conduit's surface and minimizing directional changes in the flow of the activated reactive gas. In this regard, the flow of activated reactive gas from the openings of the distribution conduit is in direct flow communication with the surface of the substrate to be treated to minimize recombination of the activated species. In other words, the activated reactive gas flows in an unobstructed, preferably relatively straight, flow path between distribution conduit's openings and the surface to be treated. Similarly directional changes within the conduit are likewise minimized by, e.g., avoiding excess bends, baffles, tube-in-tube arrangements known in the art or avoiding diffusion through porous layers. For example, the openings in the distribution conduit may be slots that are parallel to the main path of flow and are chamfered at the edges of the one or more openings to minimize the amount of exposed area in contact with the activated reactive gas. The openings are in any case distinguished by their size, shape, and intentional placing from pores. In certain embodiments, the substrate having a wide and/or long surface area to be treated can be mounted on a conveyor system to enable continuous surface modification or treatment. In these embodiments, the substrate may be moved and the processing chamber is fixed in place. In alternative embodiments, at least a portion of the processing chamber may be movable with respect to the substrate to enable continuous surface modification or treatment. In the later embodiments, the substrate may be fixed in place. The processing chamber may be designed to treat the substrate in a variety of positions, such as but not limited to, a horizontal position, a vertical position, or an angled position. The processing chamber is adapted to hold at least part of the substrate. In certain embodiments the processing chamber is adapted to hold the entire substrate. For endless substrates, partial holding is utilized. The chamber thus needs not have, but preferably has slightly larger dimensions than the substrate. It preferably resembles the substrate's shape, at least in one dimension. For endless substrates, it is most preferably arranged perpendicular/orthogonal to the endless dimension. The distribution conduit(s) is/are preferably arranged on at least one side of the chamber, most preferably over the entire length thereof. The exhaust manifold may be arranged anywhere in the chamber. For certain embodiments, it may be preferred to arrange the manifold on the side facing the distribution conduit(s). Most preferably, the exhaust manifold may comprises a plurality of openings that are substantially similar in size and geometry and positioned facing the openings in the distribution conduit.

Several approaches for treating large surface areas of substrates are disclosed herein. In one embodiment, remotely activated reactive gas may be introduced into the processing chamber through a plurality of distribution conduits that are shaped like shower heads and arranged in such a manner to enable surface treatment of large areas. The shower head-shaped distribution conduits can be fed from a single activation energy supply source or by separate activation energy supply sources for each distribution conduit. In another embodiment, a remotely activated reactive gas is introduced into the processing chamber through one or more narrow but long distribution conduits designed to provide uniform distribution of activated reactive gas.

The length of one or more conduits preferably covers the entire width or the length of the substrate. The entire surface of the large area of the substrate may be treated either by moving the conduit along the length of the substrate or moving the substrate relative to the conduit. The one or more conduits can be fed from a single activation energy source or by a dedicated activation energy source for each conduit. In yet another embodiment, a reactive gas is activated inside one or more narrow but long chambers that are in fluid communication with a distribution conduit having multiple openings. The reactive gas is activated within the narrow and long chamber and then introduced into the treatment chamber via openings within the distribution conduit. The length of one or more chambers covers entire width or length of the substrate. The entire surface of the large area of the substrate may be treated either by moving the conduit along the width or length of the substrate or moving the substrate relative to the conduit. In a still further embodiment, wide, long, and/or large surface areas of the substrate that is oriented vertically can be treated by contacting at least a portion of the substrate with an activated reactive gas that flows substantially parallel to the surface of the substrate. In this embodiment, one or more distribution conduits are arranged proximal to the base of the substrate and one or more exhaust manifolds are arranged proximal to the top of the substrate. The reactive gas is activated and is forced through the opening of the distribution conduit and upward via carrier gas flow, vacuum, or both thereby contacting at least a portion of the substrate surface. One or more back plates, which could be a separate plate constructed of a material that will not deactivate the activated species or alternatively the wall of the processing chamber, can be arranged to facilitate the flow of activated reactive gas across the substrate surface. The spent activated reactive gas and/or volatile products are withdrawn from the chamber into one or more openings of the exhaust manifold. In this embodiment and other embodiments discussed herein, the one or more openings of the distribution conduit are in relative alignment to the one or more openings within the exhaust manifold. In certain embodiments, more than one surface of the substrate can be treated at the same time.

The substrates to be treated in accordance with this disclosure may be substantially flat or exhibit a slight curvature. Exemplary substrates that may be treated include, but are not limited to, semiconductor materials such as gallium arsenide (“GaAs”), boronitride (“BN”), silicon, and compositions containing silicon such as crystalline silicon, polysilicon, amorphous silicon, epitaxial silicon, silicon dioxide (“SiOₓ or SiO₂”), silicon carbide (“SiC”), silicon oxycarbide (“SiOₓC_{y}”), silicon nitride (“SiNₓ”), silicon carbonitride (“SiCₓN_{y}”), a wide variety of glasses including float glass, soda lime glass, and borosilicate glass, organosilicate glasses (“OSG”), organofluorosilicate glasses (“OFSG”), fluorosilicate glasses (“FSG”), metals, semi-metals, polymers, plastics, ceramics and other appropriate substrates or mixtures thereof. Preferably, the substrate to be treated is a glass substrate such as float glass, soda lime glass, and borosilicate glass, organosilicate glasses (“OSG”), organofluorosilicate glasses (“OFSG”), fluorosilicate glasses (“FSG”) that are used, for example, in architectural applications, screens, optical glass, transporation vehicles, and other applications wherein large surface areas of glass need to be treated. Substrates may further comprise a variety of layers or coatings to which the film is applied thereto such as, for example, antireflective coatings, antiscratch coatings, hard coatings such as silicon oxide, silicon nitride, silicon carbonitrides, and titania, low-emission coatings deposited by chemical vapor deposition or physical vapor deposition, photoresists, organic polymers, porous organic and inorganic materials, metals such as copper and aluminum, thermal barrier layer, and/or diffusion barrier layers such as binary and/or transition metal ternary compounds.

At least a portion of a process gas comprising one or more reactive gases is activated by one or more energy sources to form an activated reactive gas. The amount of reactive gas present within the process gas may range from about 0.1% to about 100%, from about 0.5% to about 50%, or from about 1% to about 25% based upon the total volume of process gas. Exemplary reactive gases used for treating at least a portion of the substrate surface include, but are not limited to, halogen-containing gases (e.g., fluorine, chlorine, bromine, etc.), oxygen-containing gases, nitrogen-containing gases, and mixtures thereof. The process gas and/or reactive gas(es) contained therein can be delivered to the activation site by variety of means, such as, but not limited to, conventional cylinders, safe delivery systems, vacuum delivery systems, and/or solid or liquid-based generators that create the reactive source at the point of use.

In certain embodiments, the reactive gas may comprise a fluorine-containing gas. Examples of fluorine-containing gases suitable for the process described herein include: HF (hydrofluoric acid), F₂ (fluorine), NF₃ (nitrogen trifluoride), SF₆ (sulfur hexafluoride), SF₄ (sulfur tetrafluoride), sulfoxyfluorides such as SOF₂ (thionyl fluoride) and SO₂F₂ (sulfuryl fluoride), FNO (nitrosyl fluoride), XeF₂ (xenon fluoride), BrF₃ (bromine fluoride), C₃F₃N₃ (cyanuric fluoride); perfluorocarbons such as CF₄, C₂F₆, C₃F₈, C₄F₈ etc., hydrofluorocarbons such as CHF₃ and C₃F₇H etc., oxyfluorocarbons such as C₄F₈O (perfluorotetrahydrofuran), C₂F₂O₂ (oxalyl fluoride), COF₂, etc., oxygenated hydrofluorocarbons such as hydrofluoroethers (e.g. methyltrifluoromethyl ether —CH₃OCF₃), hypofluorites such as CF₃—OF (fluoroxytrifluoromethane (FTM)) and FO—CF₂—OF (bis-difluoroxy-difluoromethane (BDM)), etc., fluoroperoxides such as CF₃—O—O—CF₃ (bis-trifluoro-methyl-peroxide (BTMP)), F—O—O—F etc., fluorotrioxides such as CF₃—O—O—O—CF₃ etc., fluoroamines such a CF₅N (perfluoromethylamine), fluoronitriles such as C₂F₃N (perfluoroacetonitrile), C₃F₆N (perfluoroproprionitrile), and CF₃NO (trifluoronitrosylmethane), and COF₂ (carbonyl fluoride).

In certain embodiments, the reactive gas may comprise a chlorine-containing gas. Examples of chlorine-containing gases suitable for the process described herein include BCl₃, COCl₂, HCl, Cl₂, ClF₃, and NFₓCl₃₋ₓ, where x is an integer from 0 to 2, chlorocarbons, and chlorohydrocarbons (such as CₓH_{y}Cl_{z}, where x is a number ranging from 1 to 6, y is a number ranging from 0 to 13, and z is a number ranging from 1 to 14).

In certain embodiments, the reactive gas can further contain an oxygen-containing gas. Exemplary oxygen-containing gases include O₂, O₃, CO, CO₂, NO₂, H₂O, and N₂O. This may be preferred for certain embodiments wherein a halogen-containing gas is the reactive gas.

In embodiments wherein the process gas is not entirely comprised of reactive gas(es), the process gas also comprises one or more additive gases. Examples of additive gases include hydrogen, nitrogen, helium, neon, argon, krypton, and xenon. It is believed that, in certain embodiments, the additive gas can modify the plasma characteristics to better suit some specific applications. In these and other embodiments, the additive gas may also aid in transporting the reactive gas and/or activated reactive gas to the substrate or process chamber. The amount of additive gas present within the process gas may range from 0% to 99.9%, or from about 25% to about 99.5%, or from 50% to about 99.5%, or from about 75% to about 99.9%, by volume based upon the total volume of process gas.

The reactive gas within the process gas may be activated by one or more energy sources such as, but not limited to in situ plasma, remote plasma, remote thermal/catalytic activation, in-situ thermal heating, electron attachment, and photo activation. These processes may be used alone or in combination. Preferably, the reactive gas is activated by a plasma energy source such as remote plasma, in situ plasma, and combinations thereof. More preferably, the reactive gas is activated by a remote plasma. This may be augmented by other types of activation.

In thermal heating activation, the processing chamber and apparatus contained therein may be heated either by resistive heaters or by intense or infrared lamps. Reactive gases are thermally decomposed remotely into active species, i.e., reactive radicals and atoms that subsequently react with at least a portion of the substrate surface. Elevated temperature may also provide the energy source to overcome reaction activation energy barrier and enhance the reaction rates. For thermal activation, the substrate can be heated to at least 50° C., or at least 300° C., or at least 500° C. In embodiments wherein at least one of the fluorine-containing gases is NF₃, the substance can be heated up to at least 300° C., or at least 400° C., or at least 600° C. In these embodiments, the temperature may range from about 450° C. to about 700° C. Different reactive gases may use different temperature ranges. For example, if the reactive gas contains ClF₃ or F₂ as the fluorine-containing gas, the temperature may range from about 100° C. to about 700° C. In any of these embodiments, the pressure may range from 10 millitorr (mTorr) to 760 Torr, or from 1 Torr to 760 Torr. The pressure in the chamber can be controlled and/or adjusted by using known pressure control devices.

In embodiments wherein an in situ plasma source is used to activate the reactive gas, fluorine-containing gas molecules such as NF₃ may be broken down by the discharge to form reactive fluorine-containing ions and radicals. The fluorine-containing ions and radicals can react with the surface of the substrate to form volatile species that can be removed from the process chamber by vacuum pumps or similar means. For in situ plasma activation, the in situ plasma can be generated with a 13.56 MHz RF power supply, with RF power density of at least 0.2 W/cm², or at least 1 W/cm², or at least 3 W/cm². Alternatively, the in situ plasma can be operated at RF frequencies lower or higher than 13.56 MHz. The in-situ plasma can also be generated by DC discharge. The operating pressure may range from 2.5 mTorr to 100 Torr, or from 5 mTorr to 50 Torr, or from 10 mTorr to 20 Torr. In one particular embodiment, the process is conducted at a pressure of 5 torr or less. In these embodiments, an in situ energy source, such as in situ RF plasma activation can be combined with a thermal and/or remote energy source. The pressure in the chamber can be controlled and/or adjusted by using known pressure control devices.

In certain preferred embodiments, a remote energy source, such as, but not limited to, a remote plasma source such as RF, DC discharge, microwave, or ICP activation, a remote thermal activation source, and/or a remote catalytically activated source (i.e., a remote source which combines thermal and catalytic activation), can be used to activate the reactive gas. In remote plasma activation, the process gas having reactive gas contained therein is activated to form an activated reactive gas outside of the processing chamber which is introduced into the processing chamber to treat at least a portion of the substrate. The operating pressure of the remote plasma activation source may range from 5 mTorr to 100 Torr or from 5 mTorr to 50 Torr. The operating pressure of the processing chamber may range from 5 mTorr to 100 Torr or from 5 mTorr to 50 Torr. The pressure in the chamber can be controlled and/or adjusted by using known pressure control devices. In remote thermal activation, the process gas first flows through a heated area outside of the process chamber. The gas dissociates by contact with the high temperatures within in a location outside of the process chamber. Alternative approaches include the use of a remote catalytic converter to dissociate the process gas, or a combination of thermal heating and catalytic cracking to facilitate activation of the reactive gas within the process gas. In these embodiments, reactions between remote plasma generated reactive species and the substrate surface can optionally be activated/enhanced by heating the substrate to temperatures of at least 100° C., or at least 300° C., or at least 400° C., or at least 600° C.

The remotely activated reactive gas is distributed inside a vacuum chamber using an apparatus that is designed to provide uniform and complete coverage of the wide and/or long surface areas of material with activated reactive gas and to minimize the loss in effectiveness of the activated species present in the activated reactive gas due to recombination of the activated species.

In one aspect, the invention is an apparatus for treatment of at least a portion of a surface of a substrate with an activated reactive gas, wherein the apparatus includes the following:
(a) a processing chamber having an inner volume and being in communication with the substrate;
(b) an exhaust manifold disposed in the processing chamber;
(c) a conveyor in communication with the processing chamber and the substrate, the conveyor being adapted to sequentially introduce into the processing chamber untreated portions of the substrate for said treatment and to sequentially remove from the processing chamber treated portions of the substrate;
(d) the substrate in communication with the processing chamber and the conveyor, the substrate having a length and a width, wherein the length of the substrate exceeds a dimension of the inner volume of the processing chamber;
(e) a distribution conduit disposed in the processing chamber, the distribution conduit having a length, an entry port for the process gas or the activated reactive gas, and a plurality of openings for directing a process gas or the activated reactive gas into the inner volume, wherein the length of the distribution conduit is approximately equal to the width of the substrate, and wherein the distribution conduit has a number (N) of openings, each opening has a cross sectional area (Aₒ), and a cross sectional area of the distribution conduit (A_{c}), and wherein a maximum cross-sectional area (N*Aₒ) of the openings can be determined by the following expression:
   1.0*A_{c}>N*Aₒ≧0.1*A_{c};
(f) a supply of a process gas; and
(g) an energy source for activating the process gas in fluid communication with the processing chamber and the distribution conduit.

In certain embodiments, a large portion of the surface area of the substrate may be treated at one time by covering the entire width or length of the material by the distribution system and moving the substrate on a conveyor belt. Alternatively, the distribution conduit can be moved with respect to the substrate and the substrate is fixed in place. In these embodiments, the distribution conduit may substantially cover the width or length of the substrate but only a portion of the width or length of the substrate is covered. This may allow a single distribution conduit to treat substantially the entire width or length and a segment of the width or length of the substrate. The entire width or length of the substrate can then be treated by controlling speed of the conveyor belt and/or the distribution conduit(s).

In alternative embodiments, a plurality of distribution conduits may be used. In these embodiments, the distribution conduits may be placed in parallel or in other configurations to cover part of the length of the material. For substrates having a width of eight feet or greater, two or more distribution conduits, each conduit being from 6 to 8 feet in length can be arranged consecutively from either side of the substrate to substrate surface that is 16 to 18 feet wide. In still further embodiments, the main feed into the distribution conduits from the supply source can be split into parallel pipes to cover at least a portion of the length of the substrate. It is believed that using a plurality of distribution conduits may prevent the active species within the activated reactive gas from recombining if the length of the distribution conduit becomes too long or the residence time of activated reactive gas in the distribution conduit is too greater. In this and other embodiments, multiple activation supply sources may be employed to feed one or more multiple distribution conduits.

In one embodiment of the method described herein, a large substrate having a length of greater than 2 feet and a width of greater than 1 foot, and/or a surface area of 2 square feet or greater is placed onto a conveyor belt that is passed into a processing chamber. The processing chamber has a distribution conduit that is mounted perpendicular to the mouth of the processing chamber and has multiple openings through which an activated reactive gas passes through. The activated reactive gas contacts at least a portion of the substrate surface and forms a spent activated reactive gas and/or volatile by-product. The spent activated reactive gas and/or volatile by-products pass out of the processing chamber through exhaust manifold by a vacuum pump. In certain embodiments, it may be desirable to preheat the surface to be treated to improve efficiency of surface treatment by activated reactive gas. Therefore, the surface to be treated can be pre-heated to a temperature varying from ambient temperature to about 50° C., or from ambient temperature to about 250° C., or from ambient temperature to about 400° C.

For substrates having a width of eight feet or greater, two or more distribution conduits, each conduit being from 6 to 8 feet in length can be arranged consecutively from either side of the substrate to substrate surface that is 16 to 18 feet wide. In still further embodiments, the main feed into the distribution conduits from the supply source can be split into parallel pipes to cover at least a portion of the length of the substrate. It is believed that using a plurality of distribution conduits may prevent the active species within the activated reactive gas from recombining if the length of the distribution conduit becomes too long or the residence time of activated reactive gas in the distribution conduit is too greater. In this and other embodiments, multiple activation supply sources may be employed to feed one or more multiple distribution conduits.

In certain embodiments, the energy source is selected from the group consisting of a remote plasma source, an in situ plasma source, and combinations thereof and optionally assisted by a remote thermal energy source, a catalytic energy source, an in-situ thermal energy source, electron attachment, a photon-based energy source, and combinations thereof. Preferably, the energy source is a remote plasma energy source.

In certain embodiments, the processing chamber further comprises a pressure regulator to adjust an operating pressure of the chamber to less than 760 torr (101.3 kPa).

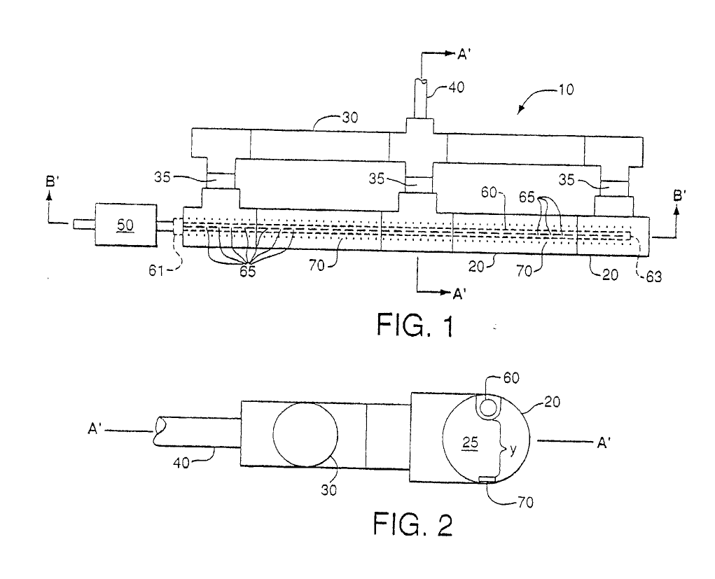

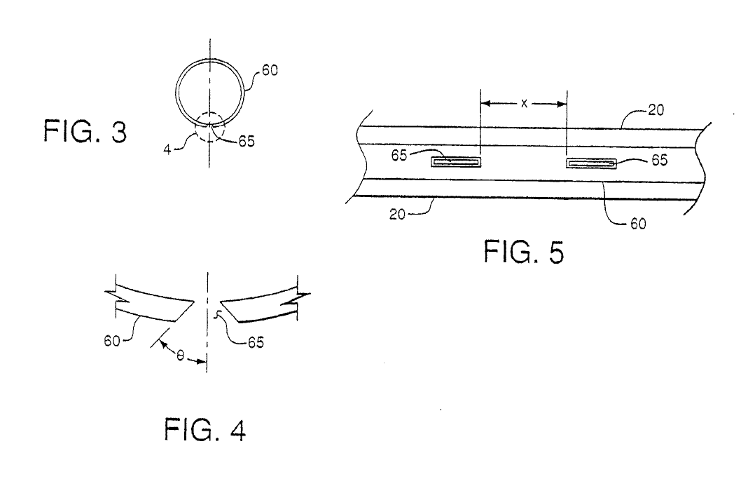

FIGS. 1 through 5 provide an example of one embodiment of the apparatus for introducing a remotely activated reactive gas described herein. Apparatus 10 is comprised of a processing chamber 20 where at least a portion of the surface of the substrate 70 (shown in dotted line in FIG. 1) is treated, an activated reactive gas supply source 50, a distribution conduit 60 (shown in dashed line in FIG. 1), an exhaust manifold 30, and outlet 40 to a vacuum pump (not shown). In certain embodiments, processing chamber 20 is a vacuum chamber or operates at pressures below 760 Torr. Distribution conduit 60 has a substantially continuous inner volume that is in fluid communication with supply source 50 of the activated species of the process gas, such as for example, a remote plasma activation chamber, and the inner volume 25 of processing chamber 20. Distribution conduit 60 may have a circular, elliptical, ovular, square, or rectangular cross section. In certain embodiments, the distribution conduit has a rounded cross-section such as a circular, elliptical, ovular, etc., to facilitate flow of the activated species through the conduit and minimize areas of stagnation. In the embodiment depicted in FIGS. 1 through 5, distribution conduit is a cylindrical pipe. In these embodiments, the inner diameter of the pipe may be at least one inch or greater.

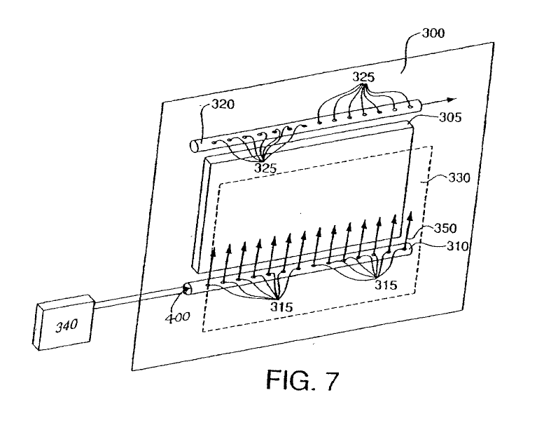

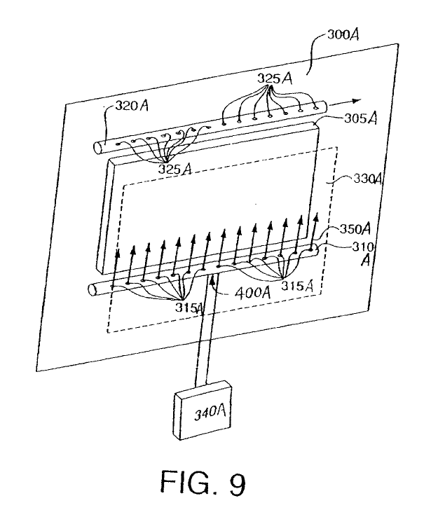

Distribution conduit 60 has a one or more openings 65, preferably a plurality of openings (see FIGS. 1 and 3 through 5), which allow the activated reactive gas to flow from supply source 50 to inner volume 25 of processing chamber 20. It is challenging to design a gas distribution system to provide uniform distribution of an activated process gas over a large area because one would have to select proper values for four independent variables such as flow rate of activated process gas, a diameter of a distribution conduit, an area of openings and a number of openings to provide uniform distribution of the activated process gas in the chamber. Consequently, computational fluid dynamic modeling was used as a tool to evaluate many different distributor designs and flow conditions to identify suitable designs of distribution systems that introduces activated process gas without splitting the activated process gas (for example, as shown in FIG. 7) and with splitting the activated process gas (for example, as shown in FIG. 9 using a T-shaped distributor) within the distribution system.

In certain embodiments, the maximum total cross-sectional area of the openings, or the sum of the cross-sectional areas of openings 65 within distribution conduit 60, may be selected by providing the ratio of kinetic energy of the inlet stream of activated reactive gas into distribution conduit 60 to pressure drop across opening 65 to be equal to or less than one-tenth.

Opening(s) 65 may have a variety of geometries including but not limited to, circular, square, rectangular, oval, or slot. In embodiments where distribution conduit 60 has one opening 65, opening 65 is a long, narrow slot. Opening(s) 65 in the distribution conduit 60 may exhibit any geometry as long as the criteria related to the maximum total cross-sectional area is maintained. In embodiments wherein the geometry of opening 65 is rectangular in shape, it is preferred to orient the longest dimension of opening 65 parallel to the gas flow along the distribution conduit 60. In certain embodiments, such as that shown in FIG. 4, the sidewalls of opening 65 may be angled or chamfered at an angle ⊖ of at least 20° or greater, or at least 30° or greater or at least 45° or greater, to minimize the amount of contact of activated reactive gas with the side walls. To improve the flow of the activated reactive gas through distribution conduit 60, at least one end 63 of the distribution conduit 60, or the end opposite the activated reactive gas inlet 61, is closed.

In certain embodiments, each opening has a diameter (d_{O}) of at least 0.1 mm (4 mil), preferably at least 0.5 mm (20 mil), more preferably at least 1 mm (0.04 inch), and of at most 50 mm (1.95 inch), preferably at most 20 mm (0.78 inch), and most preferably 5 mm (0.2 inch).

In certain embodiments, the distribution conduit has a number of openings (N) in the range of 2 to 500, preferably 5 to 100, most preferably 10 to 50.

In certain embodiments, uniform distribution of activated reactive gas along the length of distribution conduit 60 can be achieved by carefully selecting the distance “x” (see FIG. 5) between two of the plurality of openings 65 in distribution conduit 60 and/or the distance “y” (see FIG. 2) between opening 65 and the surface of the substrate 70 to be treated. The measurements for “x” and “y” may vary depending upon the geometry and features of apparatus 10. In these embodiments, distance “y” may be also used to calculate the appropriate chamfer angle and geometry of opening 65. For example, the maximum cross sectional area of each opening 65 can be calculated by dividing the maximum total cross sectional opening flow area by the total number of openings desired along the length of the distribution conduit 60. The information about the desired number of openings and shape and size of the openings is then used to determine the distance “x” assuming that the flow of activated reactive gas diverged by an angle of 10° in each direction once it passed by the edge of the opening 65. The shape and size of the openings and the pitch that provide overlap of the gas passing from each opening when it reaches the substrate surface then determines the pitch of the opening. In other embodiments, each opening 65 has a sidewall that is chamfered at an angle α, each opening is spaced apart from each other opening by a distance x, and the distribution conduit is spaced apart from the surface to be treated by a distance y such that:
x/(2*tan α)≦y.

In certain embodiments, each opening is spaced apart from each other opening by a distance (x) in the range of 0.1 to 250 cm (0.04-98 inch), preferably 0.5 to 85 cm (0.2-33 inch), and most preferably 5 to 25 cm (2-10 inch).

In certain embodiments, the sidewall is chamfered at the angle of at least 20°.

In certain embodiments, the distance (y) is in a range of about 0.4 inch to about 60 inch (1 cm to 150 cm). Preferably, the distance (y) is in the range of about 2 inch to about 8 inch (5.08 cm to 20.32 cm). In certain embodiments, distance (y) may range from about 1 to about 8 inches, and preferably from about 2 to about 6 inches.

In certain embodiments, the plurality of openings in the distribution conduit is distributed approximately uniformly over a portion of the distribution conduit closest to the surface of the substrate presented for said treatment.

In certain embodiments, the distribution conduit is a tube having a longitudinal axis and the openings are disposed in a line substantially parallel to the longitudinal axis of the tube and on a side of the tube which is closest to the surface of the substrate presented for said treatment.

In certain embodiments, at least one of the length and the width of the substrate is greater than 1 foot (30.48 cm). In certain embodiments, at least one of the length and the width of the substrate is at least 4 feet (121.92 cm). Preferably, the surface area of the substrate is at least 2 square feet (0.185 m²).

In a preferred embodiment, the distribution conduit is substantially parallel to the surface of the substrate.

Preferably, the openings of the distribution conduit are adapted to dispense the process gas or the activated reactive gas in a direction perpendicular to the surface of the substrate during said treatment.

The apparatus and the method of this invention are not intended for applications involving depositing a film or a layer by CVD or plasma CVD.

The spent activated reactive gas, and/or volatile products if present, may be removed from inner volume 25 of the processing chamber 20 via one or more conduits 35 to exhaust manifold 30. In certain embodiments, exhaust manifold 30 may have one or more openings (not shown) that are oriented to be in relative alignment within the one or more openings 65 in distribution conduit 60. In these embodiments, exhaust manifold 30 may contain openings that are substantially similar in size and geometry to openings 65 in distribution conduit 60 and positioned facing openings 65 such that substantially equal laminar flow in one direction is obtained. In these embodiments, the maximum total cross sectional area of the openings for the exhaust manifold is same as, or preferably greater than, the maximum total cross sectional area of the openings for the distribution conduit. The spent reactive gas may be exhausted out of the exhaust manifold 30 via outlet 40 to a vacuum pump (not shown). In certain embodiments, the spent activated reactive gas can be treated to remove harmful components prior to venting to outside environment and/or recycling back into supply source 50.

The time of flight of activated reactive gas, from supply source 50 to inner volume 25 to surface of substrate 70, may vary depending upon one or more of the following operating parameters such as, for example, the total operating pressure of apparatus 10 (which includes the flow rate of activated reactive gas and any additional additive gases), distance of flow from supply source 50 to substrate 70, mass flow rate of reactive gas, mass flow rate of other additive gases combined with the activated reactive gas, etc. In certain embodiments, any one or more of the foregoing operating parameters are varied to provide a time of flight of activated species of about 1.0 second or less or about 0.5 seconds or less. In these embodiments, the operating pressure in the processing chamber can vary from about 1 millitorr to about 100 torr, or from about 5 millitorr to about 50 torr, or from about 5 millitorr to about 10 torr.

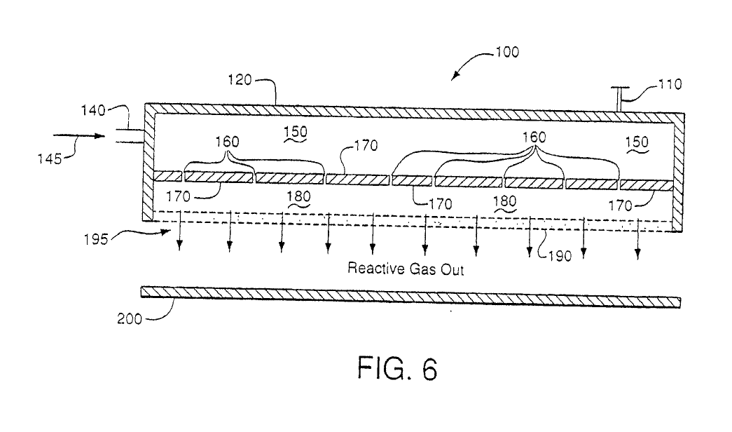

In certain embodiments, the reactive gas can be distributed inside a vacuum chamber for in-situ activation using an apparatus that is designed to provide uniform and complete coverage of the width or length of the material with activated reactive gas. FIG. 6 provides an example of one such embodiment of the apparatus described herein for introducing reactive gas for in-situ activation. Apparatus 100 is comprised of a distribution conduit 120 mounted inside a processing chamber (not shown) where at least a portion of the surface of substrate 200 is treated. The processing chamber is comprised of a closed-ended, hollow distribution conduit 120 and a process gas inlet 140 for providing uniform distribution of the process gas into the processing chamber. Process gas flows into distribution conduit 120 through inlet 140 as shown by arrow 145. In certain embodiments, an exhaust manifold (not shown) is attached via exhaust outlet to the processing chamber to facilitate evacuation of used or spent activated reactive gas with a vacuum pump (not shown). In certain embodiments, distribution conduit 120 further includes a perforated or porous, metallic or ceramic layer 190 that has a perforation or pore size greater than the mean free path of the reactive gas used for treating the surface of the substrate. The process gas is fed to the upper portion 150 of the distribution conduit 120 through an inlet pipe 140 connected to the process gas supply source (not shown). The hollow metallic distribution conduit may include a distribution baffle 170 containing multiple, uniformly spaced apertures 160 designed to distribute the reactive gas uniformly throughout the length of the bottom portion 180 of distribution conduit 120. In one particular embodiment, baffle 170 separating the upper and lower portions 150 and 180 of distribution conduit 120 may consists of, for example, a stainless steel plate having holes ranging in size from 1 to 2 millimeter (mm) that are spaced every 10 to 20 centimeter (cm) along the main axis of the plate. The perforated or porous layer 190 can have size of perforation or pores varying from 0.1 microns to about 50 microns. In certain embodiments, baffle 170 may allow for the gas pressure against the bottom porous layer 190 to be uniform and consistent through feed fluctuations. Porous layer 190 is made of metallic or ceramic material for in-situ thermal and/or catalytic activation of reactive gas. In embodiments wherein the reactive gas is activated by in-situ plasma activation, porous layer 190 comprises a metallic material. In these embodiments, RF power is applied through a power line 110 for in-situ activation of reactive gas with plasma. The activated reactive gas flows out of distribution conduit 120 through porous layer 120 as shown by arrows 195 and contacts at least a portion of the surface of substrate 200. Like distribution conduit 60 in FIG. 1, distribution conduit 120 may have a circular, elliptical, ovular, square, or rectangular cross section.

In yet another aspect, the invention is a process for treatment of at least a portion of a surface of a substrate with an activated reactive gas, wherein the process includes:
(1) providing a processing chamber, the processing chamber having an inner volume and an exhaust manifold disposed in the processing chamber;
(2) providing a conveyor in communication with the processing chamber and the substrate;
(3) placing the substrate having a length and a width in communication with the processing chamber and the conveyor, wherein the length of the substrate exceeds a dimension of the inner volume of the processing chamber;
(4) providing a distribution conduit inside the processing chamber, the distribution conduit having a length and a plurality of openings, wherein the length of the distribution conduit is approximately equal to the width of the substrate, and wherein the distribution conduit has a number (N) of openings, each opening has a cross sectional area (Aₒ), and a cross sectional area of the distribution conduit (A_{c}), and wherein a maximum cross-sectional area (N*Aₒ) of the openings can be determined by the following expression:
   1.0*A_{c}>N*Aₒ≧0.1*A_{c};
(5) providing a supply of a process gas, the process gas comprising a reactive gas and optionally an additive gas;
(6) providing an energy source in fluid communication with the processing chamber and the distribution conduit;
(7) activating the process gas with the energy source to generate the activated reactive gas;
(8) delivering the process gas or the activated reactive gas to the distribution conduit through the entry port;
(9) removing a spent process gas via the exhaust manifold;
(10) directing the process gas or the activated reactive gas from the distribution conduit onto the at least the portion of the surface of the substrate through the plurality of openings such that the process gas or the activated reactive gas is delivered uniformly along the width of the substrate;
(11) sequentially presenting untreated portions of the substrate for said treatment in the processing chamber and sequentially removing from the processing chamber treated portions of the substrate; and
(12) contacting the untreated portions of the substrate with the activated reactive gas and thereby providing said treatment.

In certain embodiments of the process, the energy source is selected from the group consisting of a remote plasma source, an in situ plasma source, and combinations thereof and optionally assisted by a remote thermal energy source, a catalytic energy source, an in-situ thermal energy source, electron attachment, a photon-based energy source, and combinations thereof. Preferably the energy source is a remote plasma source.

In certain embodiments of the process, the reactive gas comprises at least one of:
(i) an oxygen-containing gas, wherein the oxygen-containing gas is a member selected from the group consisting of oxygen, ozone, nitric oxide, nitrous oxide, nitrogen dioxide, carbon monoxide, carbon dioxide, water, and mixtures thereof;
(ii) a fluorine-containing gas, wherein the fluorine-containing gas is a member selected from the group consisting of hydrofluoric acid, fluorine, fluoride, perfluorocarbon, hydrofluorocarbon, oxyfluorocarbon, oxygenated hydrofluorocarbon, hypofluorite, fluoroperoxide, dioxygen difluoride, fluorotrioxide, fluoroamine, fluoronitrile, and trifluoronitrosylmethane; or
(iii) a chlorine-containing gas, wherein the chlorine-containing gas is a member selected from a group consisting of BCl₃, COCl₂, HCl, Cl₂, ClF₃, NFₓCl₃₋ₓ, where x is an integer ranging from 0 to 2, chlorocarbons, chlorohydrocarbons, and mixtures thereof.

In certain embodiments of the process, the fluorine-containing gas is a member selected from a group consisting of NF₃; SF₆; SF₄; SOF₂, SO₂F₂, COF₂, C₂F₂O₂, C₄F₈O, NOF, C₃F₃N₃, XeF₂, BrF₃, CF₄, C₂F₆, C₃F₈, C₄F₈, CHF₃, C₃F₇H, CH₃OCF₃, CF₃OF, FOCF₂OF, CF₃O₂CF₃, CF₃O₃CF₃, CF₅N, C₂F₃N, C₃F₆N, and mixtures thereof.

In certain embodiments of the process, the process gas comprises an additive gas. Non-limiting examples of the additive gases include H₂, N₂, He, Ne, Kr, Xe, Ar, and mixtures thereof.

In certain embodiments of the process, said directing of the process gas or the activated reactive gas through the plurality of openings of the distribution conduit is conducted in a direction substantially perpendicular to the surface of the substrate during said treatment and wherein the distribution conduit is arranged to be substantially parallel to the surface of the substrate.

In certain embodiments of the process, the substrate comprises glass.

In certain embodiments of the process, said contacting is conducted at a pressure below 760 torr (101.3 kPa).

In certain embodiments of the process, the treatment is at least one of oxidation, reduction, nitriding, carburization, halogenation, roughening, smoothening, cleaning, or etching.

In certain embodiments of the process, the treatment excludes layer depositions.

In yet another aspect, the invention is a process for treatment of at least a portion of a surface of a substrate with an activated reactive gas, wherein the process includes:
(1) providing a processing chamber, the processing chamber having an inner volume and an exhaust manifold disposed in the processing chamber;
(2) providing a conveyor in communication with the processing chamber and the substrate;
(3) placing the substrate having a length and a width in communication with the processing chamber and the conveyor, wherein the length of the substrate exceeds a dimension of the inner volume of the processing chamber;
(4) providing a distribution conduit inside the processing chamber, the distribution conduit having a length, an entry port for the process gas or the activated reactive gas, and a plurality of openings for directing a process gas or the activated reactive gas into the inner volume, wherein the length of the distribution conduit is approximately equal to the width of the substrate, and wherein each opening of the distribution conduit has a sidewall chamfered at an angle (α), each opening is spaced apart from another opening by a distance (x), and the distribution conduit is disposed at a distance (y) from the substrate presented for said treatment such that
   x/(2*tan α)≦y;
(5) providing a supply of a process gas, the process gas comprising a reactive gas and optionally an additive gas;
(6) providing an energy source in fluid communication with the processing chamber and the distribution conduit;
(7) activating the process gas with the energy source to generate the activated reactive gas;
(8) delivering the process gas or the activated reactive gas to the distribution conduit through the entry port;
(9) removing a spent process gas via the exhaust manifold;
(10) directing the process gas or the activated reactive gas from the distribution conduit onto the at least the portion of the surface of the substrate through the plurality of openings such that the process gas or the activated reactive gas is delivered uniformly along the width of the substrate;
(11) sequentially presenting untreated portions of the substrate for said treatment in the processing chamber and sequentially removing from the processing chamber treated portions of the substrate; and
(12) contacting the untreated portions of the substrate with the activated reactive gas and thereby providing said treatment.

In yet another aspect, the invention is an apparatus for treatment of a substrate with an activated reactive gas (see, for example, FIGS. 7-10b), wherein the apparatus includes the following:
(a) a processing chamber having an inner volume and a side wall and optionally a plate, the plate being disposed between the side wall of the processing chamber and the substrate;
(b) an exhaust manifold disposed in the processing chamber;
the substrate disposed in the processing chamber in front of the side wall or the plate, the substrate having a length and a width, and wherein a distance between the substrate and the side wall or the substrate and the plate is selected to allow a uniform contact of the activated reactive gas with a surface of the substrate;
(c) a distribution conduit disposed in the processing chamber in at least one of the following configurations: (i) between the substrate and the side wall of the processing chamber or (ii) between the substrate and the plate, provided that the distribution conduit is disposed substantially parallel to the surface of the substrate, the distribution conduit having a length, an entry port for the process gas or the activated reactive gas and a plurality of openings for directing a process gas or the activated reactive gas into the inner volume, wherein said length is approximately equal to at least one of the length and the width of the substrate, and wherein the openings of the distribution conduit are adapted to dispense the process gas or the activated reactive gas in a direction substantially parallel to the surface of the substrate during said treatment;
(d) a supply of a process gas; and
(e) an energy source for activating the process gas in fluid communication with the processing chamber and the distribution conduit.

In certain embodiments, the energy source is selected from the group consisting of a remote plasma source, an in situ plasma source, and mixtures thereof and optionally assisted by a remote thermal energy source, a catalytic energy source, an in-situ thermal energy source, electron attachment, a photon-based energy source, and combinations thereof. Preferably, the energy source is a remote plasma energy source.

In certain embodiments, the distribution conduit has a number (N) of openings, each opening has a cross sectional area (Aₒ), and a cross sectional area of the distribution conduit (Ac), and wherein a maximum cross-sectional area (N*Aₒ) of the openings can be determined by the following expression:
1.0*A_{c}>N*Aₒ≧0.1*A_{c}.

In certain embodiments, the maximum cross-sectional area (N*Aₒ) of the openings can be determined by the following expression:
0.9*Ac>N*Aₒ≧0.49*A_{c}.

In certain embodiments, the maximum cross-sectional area (N*Aₒ) of the openings can be determined by the following expression:
N*Aₒ<0.49*A_{c}.

In certain embodiments, the distance between the substrate and the side wall or the plate is from about 1 cm to about 20 cm (about 0.39 inch to about 7.89 inch). Preferably, the distance between the substrate and the side wall or the plate is from about 2 cm to about 10 cm (about 0.79 inch to about 3.94 inch).

In certain embodiments, the distribution conduit is disposed at a distance from about 0.5 cm to about 10 cm (about 0.15 inch to about 3.94 inch) from the substrate.

In certain embodiments, the distribution conduit is disposed at a distance from about 1.0 cm to about 5 cm (about 0.39 inch to about 1.97 inch) from the substrate.

In certain embodiments, each opening in the distributor conduit is spaced apart from another opening at a distance of about 0.04 inch to about 10 inch (0.1 cm to 25 cm).

In certain embodiments, at least one of the length and the width of the substrate is greater than 1 foot (30.48 cm). Preferably, the surface area of the substrate is at least 2 square feet (0.185 m²).

In certain embodiments, at least one of the length and the width of the substrate is at least 4 feet (121.92 cm).

In certain embodiments, the distribution conduit is mounted in the processing chamber such that the entry port for the process gas or the activated reactive gas is disposed at a place of mounting.

In certain embodiments, the distribution conduit is mounted in the processing chamber such that the entry port for the process gas or the activated reactive gas is disposed substantially in a middle of the length of the distribution conduit.

FIG. 7 provides an isometric of one embodiment of the apparatus and system described herein wherein the substrate 305 is treated in an upright or vertical position. Apparatus 300 is comprised of a distribution conduit 310 having one or more openings 315 and an exhaust manifold 320 having one or more openings 325. The maximum cross-sectional area of openings 325 is the same as or preferably greater than the maximum cross-sectional area of openings 315. Apparatus 300 further comprises a back plate 330 which is comprised of material that prevents the active species within the reactive gas from deactivating or, alternatively back plate 330 may comprise the wall of a processing chamber. Back plate 330 directs the flow of the activated reactive gas upwards to the exhaust manifold 320. The distance between substrate 305 and back plate 330 is selected to allow a uniform contact of the activated reactive gas with the surface being treated. Such distance can be selected from about 10 mm to about 200 mm, and preferably from about 20 mm to about 100 mm. A reactive gas is activated in remote treatment area 340 which is in fluid communication with distribution conduit 310 and is delivered to an entry 400 of the distribution conduit. The activated reactive gas is directed upwards in the manner shown by arrows 350 and the spent activated reactive gas and/or volatile species after contacting substrate 305 is withdrawn from apparatus 300 using a vacuum or other means. The apparatus depicted in FIG. 7 can be readily modified to allow surface treatment of both sides of substrate 305 by adopting a similar distribution conduit, exhaust manifold, and optional back plate configuration on the opposite side of substrate 305.

FIG. 9 provides an isometric of one embodiment of the apparatus and system described herein wherein the substrate 305A is treated in an upright or vertical position. Apparatus 300A is comprised of a distribution conduit 310A having one or more openings 315A and an exhaust manifold 320A having one or more openings 325A. The maximum cross-sectional area of openings 325A is the same as or preferably greater than the maximum cross-sectional area of openings 315A. Apparatus 300A further comprises a back plate 330A which is comprised of material that prevents the active species within the reactive gas from deactivating or, alternatively back plate 330A may comprise the wall of a processing chamber. Back plate 330A directs the flow of the activated reactive gas upwards to the exhaust manifold 320A. The distance between substrate 305A and back plate 330A is selected to allow a uniform contact of the activated reactive gas with the surface being treated. A reactive gas is activated in remote treatment area 340A which is in fluid communication with distribution conduit 310A and is delivered to an entry 400A of the distribution conduit which is located substantially in the middle of the distribution conduit. The activated reactive gas is directed upwards in the manner shown by arrows 350A and the spent activated reactive gas and/or volatile species after contacting substrate 305A is withdrawn from apparatus 300A using a vacuum or other means. The apparatus depicted in FIG. 9 can be readily modified to allow surface treatment of both sides of substrate 305A by adopting a similar distribution conduit, exhaust manifold, and optional back plate configuration on the opposite side of substrate 305A.

In yet another aspect, the invention is a process for treatment of a substrate with an activated reactive gas (see, for example, FIGS. 7-10b), wherein the process includes:
(1) providing a processing chamber, the processing chamber having an inner volume, a side wall, an exhaust manifold and optionally a plate, the plate being disposed between the side wall of the processing chamber and the substrate;
(2) placing the substrate inside the processing chamber and in front of the side wall or the plate such that a distance between the substrate and the side wall or the substrate and the plate is selected to allow a uniform contact of the activated reactive gas with a surface of the substrate, the substrate having a length and a width;
(3) providing a distribution conduit inside the processing chamber, wherein the distribution conduit is provided in at least one of the following configurations: (i) between the substrate and the side wall of the processing chamber or (ii) between the substrate and the plate, such that the distribution conduit is disposed substantially parallel to the surface of the substrate, the distribution conduit having a length, an entry port for the process gas or the activated reactive gas and a plurality of openings for directing a process gas or the activated reactive gas into the inner volume, wherein said length is approximately equal to at least one of the length and the width of the substrate;
(4) providing a supply of a process gas, the process gas comprising a reactive gas and optionally an additive gas;
(5) providing an energy source for activating the process gas in fluid communication with the processing chamber and the distribution conduit;
activating the process gas with the energy source to generate the activated reactive gas;
(6) delivering the process gas or the activated reactive gas to the distribution conduit through the entry port;
(7) removing a spent process gas via the exhaust manifold;
(8) directing the process gas or the activated reactive gas from the distribution conduit onto the surface of the substrate through the openings of the distribution conduit such that the process gas is delivered uniformly along the width or the length of the substrate in a direction substantially parallel to the surface of the substrate; and
(9) contacting the surface of the substrate with the activated reactive gas and thereby providing said treatment.

In certain embodiments of the process, the energy source is selected from the group consisting of a remote plasma source, an in situ plasma source, and combinations thereof and optionally assisted by a remote thermal energy source, a catalytic energy source, an in-situ thermal energy source, electron attachment, a photon-based energy source, and combinations thereof. Preferably, the energy source is a remote plasma source.

In certain embodiments of the process, the energy source is at least one of a remote plasma source, an in situ plasma source, and combinations thereof and optionally assisted by a remote thermal energy source, a catalytic energy source, an in-situ thermal energy source, electron attachment, a photon-based energy source, and combinations thereof. Preferably, the energy source is a remote plasma source.

In certain embodiments of the process, the treatment is at least one of oxidation, reduction, nitriding, carburization, halogenation, roughening, smoothening, cleaning, or etching. Preferably, the treatment excludes layer depositions.

In certain embodiments of the process, the distribution conduit has a number (N) of openings, each opening has a cross sectional area (Ao), and a cross sectional area of the distribution conduit (Ac), and wherein a maximum cross-sectional area (N*Ao) of the openings can be determined by the following expression:
1.0*Ac>N*Ao24 0.1*Ac.

In certain embodiments of the process, said distance between the substrate and the side wall or the plate is from about 1 cm to about 20 cm (about 0.39 inch to about 7.89 inch). Preferably, said distance between the substrate and the side wall or the plate is from about 2 cm to about 10 cm (about 0.79 inch to about 3.94 inch).

### EXAMPLES

A system, that uses a remote plasma energy source to activate the reactive gas within the process gas and is similar to that depicted in FIGS. 1 through 5, was used to treat surfaces of materials in a vacuum processing chamber that was 10 inches in diameter and slightly more than eight feet long. The system was comprised of an 8-foot (ft) long, circular distribution conduit or pipe having a 1.5 inch (in) inner diameter and cross-sectional area of 1.77 in². The distribution pipe further contained 18 rectangular shaped openings for introducing an activated reactive gas. These openings were equally spaced along the length of the pipe and were directed towards the inner volume of the processing chamber. Each rectangular-shaped opening was 1.5 in length and 0.031 in width. The cross-sectional flow area of all 18 openings was 0.84 in². This provided a N*Ao/A_{c} ratio of 0.48. Both dimensions (e.g., length and width) of the openings were chamfered to about 20° to minimize contact of the activated reactive gas with the openings. The distribution pipe was mounted along the top of the processing chamber with the openings facing down into the inner volume of the processing chamber. The substrate to be treated was placed at a distance from the openings that measured from 2 to 6 inches. The distribution pipe was sealed at one end and open at the opposite end. An activated reactive gas was introduced into the pipe through the open end that was in fluid communication with an activation source for the reactive gas. The reactive gas was activated in a location outside of the vacuum processing chamber using a 13.56 MHz RF ASTRON™ plasma source manufactured by MKS Instruments of Wilmington, Mass. The activated reactive gas passed through and exited the pipe via the openings and contacted the surface of the substrate to be treated. The flow of activated gas was introduced into the gas distribution system without splitting the flow within the distribution system. The spent activated reactive gas, along with volatile products formed during the treatment, was evacuated from the vacuum processing chamber using a vacuum pump.

In some of the following examples, the surface roughness numbers were reported as an average; in other examples, the surface roughness numbers were reported as a range.

### Example 1

The vacuum processing chamber described above was used to treat the surface of two 4″ diameter silicon wafers that were thermally treated in the presence of an oxygen-containing gas to provide an approximately 470 nanometer (nm) thick silicon oxide layer with an average root mean square (rms) surface roughness of approximately 0.43 nm. The wafers were placed within the vacuum processing chamber in a location that was 8 inches and 7.5 feet from the entrance of the activated gas into the processing chamber, respectively, to approximate the extreme ends of the processing chamber.

The wafers were placed on the two extreme ends to simulate treatment of an approximately 8 foot wide substrate surface. The processing chamber was operated at a pressure of about 1.4 torr. The distribution pipe was supplied with a 1000 standard cubic centimeter per minute (sccm) flow of NF3 gas that was activated using the external RF plasma source described above. The distance of wafers from the opening was approximately 6 inches. These wafers were exposed to activated NF3 gas for a total time of 3 minutes. Thereafter, the flow of activated NF3 gas was terminated, the distribution pipe and vacuum chamber were purged with argon gas, and the treated wafers were removed for analysis. The analytical results showed that from about 60 to about 100 nm of silicon oxide layer was removed from these wafers with minor changes in the surface roughness—the surface roughness improved from about 0.43 nm to a value varying between 0.31 to 0.39 nm.

### Example 2

The surface treatment of two 4″ diameter silicon wafers with approximately 470 nanometer (nm) thick silicon oxide layer described in Example 1 was repeated in the same vacuum chamber with similar placement of wafers. The vacuum chamber was operated at a pressure of about 0.94 torr instead of using 1.4 torr pressure. The distribution pipe was supplied with a 3000 standard cubic centimeter per minute (sccm) flow of NF₃ gas that was activated using the external RF plasma source described above. The distance of wafers from the opening was approximately 6 inches. These wafers were exposed to activated NF₃ gas for a total time of 2 minutes. Thereafter, the flow of activated NF₃ gas was terminated, the distribution pipe and vacuum chamber were purged with argon gas, and the treated wafers were removed for analysis. The analytical results showed that from about 60 to about 90 nm of silicon oxide layer was removed from these wafers. The surface roughness of silicon oxide layer was noted to improve considerably from about 0.43 nm to about 0.24 nm.

### Example 3

The surface treatment of two 4″ diameter silicon wafers with approximately 470 nanometer (nm) thick silicon oxide layer described in Example 1 was repeated in the same vacuum chamber with similar placement of wafers. The vacuum chamber was operated at a pressure of about 1.4 torr. The distribution pipe was supplied with a 3000 standard cubic centimeter per minute (sccm) flow of NF₃ gas that was activated using the external RF plasma source described above. The distance of wafers from the opening was approximately 2 inches instead of using 6 inches. These wafers were exposed to activated NF₃ gas for a total time of 3 minutes. Thereafter, the flow of activated NF₃ gas was terminated, the distribution pipe and vacuum chamber were purged with argon gas, and the treated wafers were removed for analysis. The analytical results showed that from about 120 to about 250 nm of silicon oxide layer was removed from these wafers. The surface roughness of silicon oxide layer was noted to become worse from about 0.43 nm to a value varying between 0.43 and 0.76 nm.

### Example 4

The surface treatment of two 4″ diameter silicon wafers with approximately 470 nanometer (nm) thick silicon oxide layer described in Example 1 was repeated in the same vacuum chamber with similar placement of wafers. The vacuum chamber was operated at a pressure of about 1.4 torr. The distribution pipe was supplied with a 1000 standard cubic centimeter per minute (sccm) flow of a 50-50 mixture of NF₃ and argon gases. The mixture was activated using the external RF plasma source described above. The distance of wafers from the opening was approximately 2 inches. These wafers were exposed to activated NF₃ gas for a total time of 2 minutes. Thereafter, the flow of activated NF₃ gas was terminated, the distribution pipe and vacuum chamber were purged with argon gas, and the treated wafers were removed for analysis. The analytical results showed that from about 92 nm of silicon oxide layer was removed from these wafers. The surface roughness of silicon oxide layer was noted to improve from about 0.43 nm to about 0.34 nm.

### Example 5

The surface treatment of two 4″ diameter silicon wafers with approximately 470 nanometer (nm) thick silicon oxide layer described in Example 1 was repeated in the same vacuum chamber with similar placement of wafers. The vacuum chamber was operated at a pressure of about 0.94 torr. The distribution pipe was supplied with a 3000 standard cubic centimeter per minute (sccm) flow of a 50-50 mixture of NF₃ and argon gases. The mixture was activated using the external RF plasma source described above. The distance of wafers from the opening was approximately 2 inches. These wafers were exposed to activated NF₃ gas for a total time of 3 minutes. Thereafter, the flow of activated NF₃ gas was terminated, the distribution pipe and vacuum chamber were purged with argon gas, and the treated wafers were removed for analysis. The analytical results showed that from about 120 to 160 nm of silicon oxide layer was removed from these wafers. The surface roughness of silicon oxide layer was noted not to change much after the treatment.

### Example 6

The surface treatment of two 4″ diameter silicon wafers with approximately 470 nanometer (nm) thick silicon oxide layer described in Example 1 was repeated in the same vacuum chamber with similar placement of wafers. The vacuum chamber was operated at a pressure of about 0.94 torr. The distribution pipe was supplied with a 1000 standard cubic centimeter per minute (sccm) flow of a 50-50 mixture of NF₃ and argon gases. The mixture was activated using the external RF plasma source described above. The distance of wafers from the opening was approximately 6 inches. These wafers were exposed to activated NF₃ gas for a total time of 3 minutes. Thereafter, the flow of activated NF₃ gas was terminated, the distribution pipe and vacuum chamber were purged with argon gas, and the treated wafers were removed for analysis. The analytical results showed that from about 20 nm of silicon oxide layer was removed from these wafers. The surface roughness of silicon oxide layer was noted to degrade from about 0.43 nm to about 0.7 nm.

### Example 7

The procedure of Example 1 was repeated except on two 4″ diameter silicon wafers that were deposited with an approximately 300 nm thick silicon nitride coating that was deposited via plasma enhanced chemical vapor deposition technique. The average root mean square (rms) surface roughness of the silicon nitride coating was approximately 0.73 nm. The processing chamber was operated at a pressure of about 0.94 torr. The distribution pipe was supplied with 1000 sccm flow of NF₃ gas that was activated using an external RF plasma source. The distance of wafers from the opening was approximately 2 inches. These wafers were exposed to activated NF₃ gas for a total time of 3 minutes. Thereafter, the flow of activated NF₃ gas was terminated, the distribution pipe and vacuum chamber were purged with argon gas, and the treated wafers were taken out for analysis. The analytical results showed that from about 90 to 170 nm of silicon nitride coating was removed from these wafers. The surface roughness of the silicon nitride coating increased from approximately 0.73 nm to from about 7.4 to 9.5 nm.

### Example 8

The procedure of Example 7 was repeated except on two 4″ diameter silicon wafers that were deposited with an approximately 300 nm thick silicon nitride coating that was deposited via plasma enhanced chemical vapor deposition technique. The processing chamber was operated at a pressure of about 1.4 torr. The distribution pipe was supplied with 1000 sccm flow of NF₃ gas that was activated using an external RF plasma source. The distance of wafers from the opening was approximately 6 inches. These wafers were exposed to activated NF₃ gas for a total time of 2 minutes. Thereafter, the flow of activated NF₃ gas was terminated, the distribution pipe and vacuum chamber were purged with argon gas, and the treated wafers were taken out for analysis. The analytical results showed that about 100 nm of silicon nitride coating was removed from these wafers. The surface roughness of the silicon nitride coating increased slightly from approximately 0.73 nm to about 2.0 nm.

### Example 9

The procedure of Example 7 was repeated except on two 4″ diameter silicon wafers that were deposited with an approximately 300 nm thick silicon nitride coating that was deposited via plasma enhanced chemical vapor deposition technique. The processing chamber was operated at a pressure of about 0.94 torr. The distribution pipe was supplied with 3000 sccm flow of NF₃ gas that was activated using an external RF plasma source. The distance of wafers from the opening was approximately 6 inches. These wafers were exposed to activated NF₃ gas for a total time of 3 minutes. Thereafter, the flow of activated NF₃ gas was terminated, the distribution pipe and vacuum chamber were purged with argon gas, and the treated wafers were taken out for analysis. The analytical results showed that from about 100 to 120 nm of silicon nitride coating was removed from these wafers. The surface roughness of the silicon nitride coating increased slightly from approximately 0.73 nm to about 1.3 nm.

### Example 10

The procedure of Example 7 was repeated except on two 4″ diameter silicon wafers that were deposited with an approximately 300 nm thick silicon nitride coating that was deposited via plasma enhanced chemical vapor deposition technique. The processing chamber was operated at a pressure of about 0.94 torr. The distribution pipe was supplied with 1000 sccm flow of a 50-50 mixture of NF₃ and argon gases. The mixture was activated using an external RF plasma source. The distance of wafers from the opening was approximately 6 inches. These wafers were exposed to activated NF₃ gas for a total time of 2 minutes. Thereafter, the flow of activated NF₃ gas was terminated, the distribution pipe and vacuum chamber were purged with argon gas, and the treated wafers were taken out for analysis. The analytical results showed that about 60 nm of silicon nitride coating was removed from these wafers. The surface roughness of the silicon nitride coating increased from approximately 0.73 nm to about 7.0 nm.

### Example 11

The procedure of Example 7 was repeated except on two 4″ diameter silicon wafers that were deposited with an approximately 300 nm thick silicon nitride coating that was deposited via plasma enhanced chemical vapor deposition technique. The processing chamber was operated at a pressure of about 1.4 torr. The distribution pipe was supplied with 1000 sccm flow of a 50-50 mixture of NF₃ and argon gases. The mixture was activated using an external RF plasma source. The distance of wafers from the opening was approximately 2 inches. These wafers were exposed to activated NF₃ gas for a total time of 3 minutes. Thereafter, the flow of activated NF₃ gas was terminated, the distribution pipe and vacuum chamber were purged with argon gas, and the treated wafers were taken out for analysis. The analytical results showed that from about 60 to 90 nm of silicon nitride coating was removed from these wafers. The surface roughness of the silicon nitride coating increased slightly from approximately 0.73 nm to about 1.3 nm.

### Example 12

The procedure of Example 7 was repeated except on two 4″ diameter silicon wafers that were deposited with an approximately 300 nm thick silicon nitride coating that was deposited via plasma enhanced chemical vapor deposition technique. The processing chamber was operated at a pressure of about 0.94 torr. The distribution pipe was supplied with 3000 sccm flow of a 50-50 mixture of NF₃ and argon gases. The mixture was activated using an external RF plasma source. The distance of wafers from the opening was approximately 2 inches. These wafers were exposed to activated NF₃ gas for a total time of 2 minutes. Thereafter, the flow of activated NF₃ gas was terminated, the distribution pipe and vacuum chamber were purged with argon gas, and the treated wafers were taken out for analysis. The analytical results showed that from about 40 to 70 nm of silicon nitride coating was removed from these wafers. The surface roughness of the silicon nitride coating increased slightly from approximately 0.73 nm to about 1.1 nm.

### Example 13

Flow modeling of several embodiments and comparative examples of the apparatus and process described herein wherein the substrate was in a vertical or upright position (see FIG. 7) were studied using commercially available, general purpose Computational Fluid Dynamics (CFD) computer modeling software from Fluent, Inc of Lebanon, N.H. The size of the substrate was assumed to be 1.7 meters (m) by 1.3 m. The following plasma flow conditions were assumed: activated reactive gas composition 5% by volume NF₃ and 95% by volume argon; temperature of 80° F.; upstream plasma pressure of 10 Torr; processing chamber operating pressure ranging from 1-2 Torr; and activated reactive gas flow rate ranging from 1 to 4 liters per minute (lpm). The processing chamber dimensions for the CFD model were as follows: 1860 millimeter (mm) length; 1600 mm height, 835 mm depth; supply source inlet tube diameter 40 mm; and exhaust manifold outlet tube diameter 150 mm. To minimize the recombination of active species to nonactive species and control the flow of the plasma activated reactive gas, the depth of the processing chamber is preferably 1.5* the exhaust manifold outlet tube diameter or 1.5*150 mm or 225 mm.

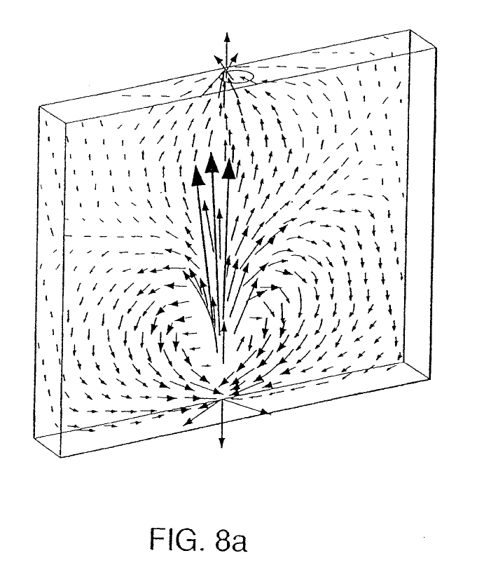

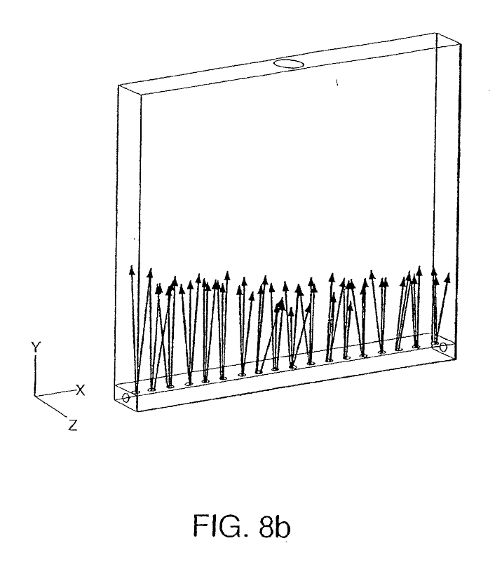

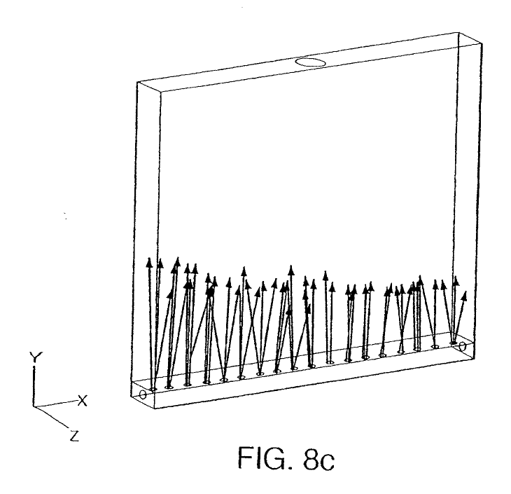

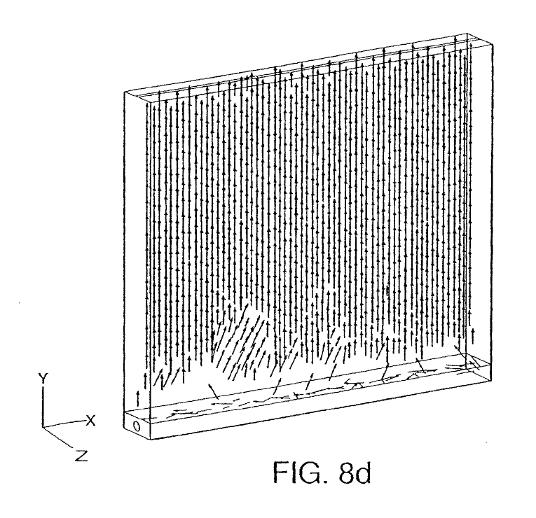

Four exemplary configurations were modeled. In comparative Example 13a, no distribution conduit was used. The plasma activated reactive gas entered the processing chamber through a single opening, supply source inlet tube having a diameter of 40 mm located and exited through a singular exhaust manifold outlet tube having a diameter of 150 mm (see FIG. 8a).

In Example 13b, the supply source inlet is connected to a 40 mm diameter horizontally positioned distribution conduit having 18 evenly spaced rectangular openings each with dimensions of 1.5″×0.031″. This provided a N*Ao/A_{c} ratio of 0.44. The plasma activated reactive gas entered the processing chamber through the multiple openings and exited through a singular exhaust manifold outlet opening having a diameter of 150 mm (see FIG. 8b). A comparison of the flow simulation between comparative Example 13a and Example 13b shows that the flow distribution in the processing chamber was more uniform by changing from a single supply inlet or one opening to a horizontal distribution conduit having 18 rectangular openings. Example 13c is similar to Example 13b except that the length of the distribution conduit rectangular openings was reduced by 20% or was was 1.2″×0.031″ rather than 1.5″×0.031″ (see FIG. 8c). This provided a N*Ao/A_{c} ratio of 0.35. Example 13d was similar to example 13c except that the exhaust manifold outlet had a singular rectangular opening or slot having a width of 0.5″ across the length of the processing chamber (see FIG. 8d). A comparison of the flow pattern of plasma activated reactive gas for Examples 13b and 13c showed that the flow distribution from the openings was improved with the smaller openings. A comparison of plasma activated reactive gas for Examples 13c and 13d showed that the flow distribution from the openings was further improved and significantly more uniform by using a larger and more decentralized opening for the exhaust manifold outlet.

### Example 14

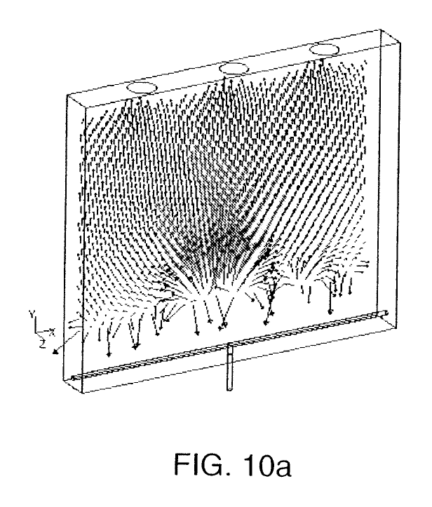

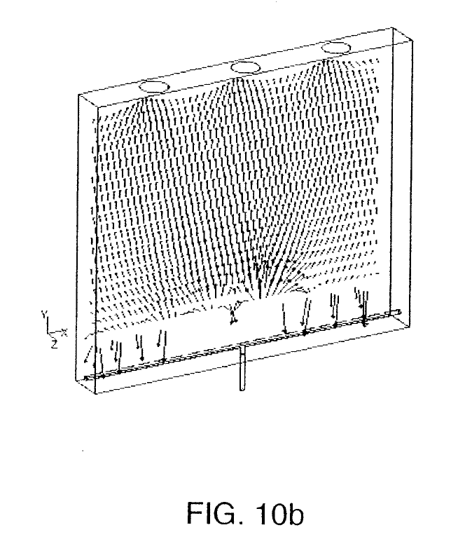

Flow modeling of several other embodiments and comparative examples of the apparatus and process described herein wherein the substrate was in a vertical or upright position (see FIG. 9) were studied using general purpose Computational Fluid Dynamics (CFD) computer modeling software from Fluent, Inc of Lebanon, N.H. The size of the substrate was assumed to be 1.7 meters (m) by 1.3 m. The following plasma flow conditions were assumed: activated reactive gas composition 5% by volume NF₃ and 95% by volume argon; temperature of 80° F.; upstream plasma pressure of 10 Torr; processing chamber operating pressure ranging from 1-2 Torr; and activated reactive gas flow rate of 1 liter per minute (lpm). The processing chamber dimensions for the CFD model were as follows: 1860 millimeter (mm) length; 1600 mm height, 835 mm depth; supply source inlet tube diameter 25 mm; and exhaust manifold containing three outlet tubes having a diameter of approximately 150 mm each (see FIG. 10a). To minimize the recombination of active species to nonactive species and control the flow of the plasma activated reactive gas, the distance between the plate and the substrate is approximately 200 mm.

Next, two exemplary configurations were modeled. In comparative Example 14a, the supply source inlet is connected in the middle of a 25 mm diameter horizontally positioned distribution conduit having 14 evenly spaced rectangular openings each with dimensions of 0.63″×0.039″. The flow of reactive process gas was thus split into two streams within the distribution system and then introduced into the processing chamber (see FIG. 10a). This provided a N*Ao/A_{c} ratio of 0.46.

In Example 14b, the supply source inlet is again connected to a 25 mm diameter horizontally positioned distribution conduit having 18 evenly spaced rectangular openings each with dimensions of 1.18″×0.031″. This provided a N*Ao/A_{c} ratio of 0.88. The plasma activated reactive gas with close to 1 lpm flow rate entered the processing chamber through the multiple openings and exited through a singular exhaust manifold outlet opening having a diameter of 150 mm (see FIG. 10b).

A comparison of the flow simulation between comparative Example 14a and Example 14b shows that the flow distribution in the processing chamber was more uniform by increasing size of the rectangular opening in the horizontal distribution conduit having 18 rectangular openings (compare FIGS. 10a and 10b).

What is claimed is:

1. An apparatus for treatment of at least a portion of a surface of a substrate with an activated reactive gas, the apparatus comprising:
a processing chamber having an inner volume and being in communication with the substrate;
an exhaust manifold disposed in the processing chamber;
a conveyor in communication with the processing chamber and the substrate, the conveyor being adapted to sequentially introduce into the processing chamber untreated portions of the substrate for said treatment and to sequentially remove from the processing chamber treated portions of the substrate;
the substrate in communication with the processing chamber and the conveyor, the substrate having a length and a width, wherein the length of the substrate exceeds a dimension of the inner volume of the processing chamber;
a distribution conduit disposed in the processing chamber, the distribution conduit having a length, an entry port for the process gas or the activated reactive gas, and a plurality of openings for directing a process gas or the activated reactive gas into the inner volume, wherein the length of the distribution conduit is approximately equal to the width of the substrate, and wherein the distribution conduit has a number (N) of openings, each opening has a cross sectional area (Aₒ), and a cross sectional area of the distribution conduit (A_{c}), and wherein a maximum cross-sectional area (N*Aₒ) of the openings can be determined by the following expression:
1.0*A_{c}>N*Aₒ≧0.1*A_{c};
a supply of a process gas; and
an energy source for activating the process gas in fluid communication with the processing chamber and the distribution conduit.

2. The apparatus of claim 1, wherein the maximum cross-sectional area (N*Ao) of the openings can be determined by the following expression:
0.9*A_{c}>N*Aₒ≧0.49*A_{c}.

3. The apparatus of claim 1, wherein the maximum cross-sectional area (N*Ao) of the openings can be determined by the following expression:
N*Aₒ<0.49*A_{c}.

4. The apparatus of claim 1, wherein the energy source is selected from the group consisting of a remote plasma source, an in situ plasma source, and combinations thereof and optionally assisted by a remote thermal energy source, a catalytic energy source, an in-situ thermal energy source, electron attachment, a photon-based energy source, and combinations thereof.

5. The apparatus of claim 1, wherein the energy source is a remote plasma energy source.

6. The apparatus of claim 1, wherein the processing chamber further comprises a pressure regulator to adjust an operating pressure of the chamber to less than 760 torr (101.3 kPa).

7. The apparatus of claim 1, wherein each opening in the distribution conduit has a diameter (dₒ) of at least 0.1 mm (4 mil).

8. The apparatus of claim 1, wherein the number (N) of openings in the distribution conduit is from about 2 to about 500.

9. The apparatus of claim 1, wherein each opening in the distribution conduit has a sidewall chamfered at an angle (α), each opening is spaced apart from another opening by a distance (x), and the distribution conduit is disposed at a distance (y) from the substrate presented for said treatment such that
x/(2*tan α)≦y.

10. The apparatus of claim 9, wherein the sidewall is chamfered at the angle of at least 20°.

11. The apparatus of claim 9, wherein the distance (y) is in a range of about 1 cm to about 150 cm (about 0.4 inch to about 60 inch).

12. The apparatus of claim 11, wherein the distance (y) is in the range of about 5.08 cm to 20.32 cm (about 2 inch to about 8 inch).

13. The apparatus of claim 9, wherein the distance (x) is in a range of about 0.1 cm to about 250 cm (about 0.04 inch to about 98 inch).

14. The apparatus of claim 1, wherein the plurality of openings in the distribution conduit is distributed approximately uniformly over a portion of the distribution conduit closest to the surface of the substrate presented for said treatment.

15. The apparatus of claim 1, wherein the distribution conduit is a tube having a longitudinal axis and the openings are disposed in a line substantially parallel to the longitudinal axis of the tube and on a side of the tube which is closest to the surface of the substrate presented for said treatment.

16. The apparatus of claim 1, wherein at least one of the length and the width of the substrate is greater than 30.48 cm (1 ft).

17. The apparatus of claim 16, wherein a surface area of the substrate is at least 0.185 m2 (2 ft2).

18. The apparatus of claim 1, wherein at least one of the length and the width of the substrate is at least 121.92 cm (4ft).

19. The apparatus of claim 1, wherein the distribution conduit is substantially parallel to the surface of the substrate.

20. The apparatus of claim 1, wherein the openings of the distribution conduit are adapted to dispense the process gas or the activated reactive gas in a direction perpendicular to the surface of the substrate during said treatment.

21. An apparatus for treatment of at least a portion of a surface of a substrate with an activated reactive gas, the apparatus comprising:
a processing chamber having an inner volume and being in communication with the substrate;
an exhaust manifold disposed in the processing chamber;
a conveyor in communication with the processing chamber and the substrate, the conveyor being adapted to sequentially introduce into the processing chamber untreated portions of the substrate for said treatment and to sequentially remove from the processing chamber treated portions of the substrate;
the substrate in communication with the processing chamber and the conveyor, the substrate having a length and a width, wherein the length of the substrate exceeds a dimension of the inner volume of the processing chamber;
a distribution conduit disposed in the processing chamber, the distribution conduit having a length, an entry port for the process gas or the activated reactive gas, and a plurality of openings for directing a process gas or the activated reactive gas into the inner volume, wherein the length of the distribution conduit is approximately equal to the width of the substrate, and wherein each opening of the distribution conduit has a sidewall chamfered at an angle (α), each opening is spaced apart from another opening by a distance (x), and the distribution conduit is disposed at a distance (y) from the substrate presented for said treatment such that
x/(2*tan α)≦y;
a supply of a process gas; and
an energy source for activating the process gas in fluid communication with the processing chamber and the distribution conduit.

22. The apparatus of claim 21, wherein the sidewall is chamfered at the angle of at least 20°.

23. The apparatus of claim 21, wherein the distance (y) is in a range of about 1 cm to about 150 cm (about 0.4 inch to about 60 inch).

24. The apparatus of claim 23, wherein the distance (y) is in the range of about 5.08 cm to about 20.32 cm (about 2 inch to about 8 inch).

25. The apparatus of claim 21, wherein the distance (x) is in a range of about about 0.1 cm to about 250 cm (about 0.04 inch to about 98 inch).

26. The apparatus of claim 21, wherein at least one of the length and the width of the substrate is greater than 30.48 cm (1 ft).

27. The apparatus of claim 26, wherein a surface area of the substrate is at least 0.185 m2 (2 ft2).

28. The apparatus of claim 21, wherein at least one of the length and the width of the substrate is at least 121.92 cm (4 ft).

29. The apparatus of claim 21, wherein the distribution conduit is substantially parallel to the surface of the substrate.

30. The apparatus of claim 29, wherein the openings of the distribution conduit are adapted to dispense the process gas or the activated reactive gas in a direction substantially perpendicular to the surface of the substrate during said treatment.

31. An apparatus for treatment of a substrate with an activated reactive gas, the apparatus comprising:
a processing chamber having an inner volume and a side wall and optionally a plate, the plate being disposed between the side wall of the processing chamber and the substrate;
an exhaust manifold disposed in the processing chamber;
the substrate disposed in the processing chamber in front of the side wall or the plate, the substrate having a length and a width, and wherein a distance between the substrate and the side wall or the substrate and the plate is selected to allow a uniform contact of the activated reactive gas with a surface of the substrate;
a distribution conduit disposed in the processing chamber in at least one of the following configurations: (i) between the substrate and the side wall of the processing chamber or (ii) between the substrate and the plate, provided that the distribution conduit is disposed substantially parallel to the surface of the substrate, the distribution conduit having a length, an entry port for the process gas or the activated reactive gas and a plurality of openings for directing a process gas or the activated reactive gas into the inner volume, wherein said length is approximately equal to at least one of the length and the width of the substrate, and wherein the openings of the distribution conduit are adapted to dispense the process gas or the activated reactive gas in a direction substantially parallel to the surface of the substrate during said treatment;
a supply of a process gas; and
an energy source for activating the process gas in fluid communication with the processing chamber and the distribution conduit.

32. The apparatus of claim 31, wherein the energy source is selected from the group consisting of a remote plasma source, an in situ plasma source, and mixtures thereof and optionally assisted by a remote thermal energy source, a catalytic energy source, an in-situ thermal energy source, electron attachment, a photon-based energy source, and combinations thereof.

33. The apparatus of claim 31, wherein the energy source is a remote plasma energy source.

34. The apparatus of claim 31, wherein the distribution conduit has a number (N) of openings, each opening has a cross sectional area (Aₒ), and a cross sectional area of the distribution conduit (A_{c}), and wherein a maximum cross-sectional area (N*Aₒ) of the openings can be determined by the following expression:
1.0*A_{c}>N*Aₒ≧0.1*A_{c}.

35. The apparatus of claim 34, wherein the maximum cross-sectional area (N*Aₒ) of the openings can be determined by the following expression:
0.9*A_{c}>N*Aₒ≧0.49*A_{c}.

36. The apparatus of claim 34, wherein the maximum cross-sectional area (N*Aₒ) of the openings can be determined by the following expression:
N*Aₒ<0.49*A_{c}.

37. The apparatus of claim 31, wherein said distance between the substrate and the side wall or the plate is from about 1 cm to about 20 cm (about 0.39 inch to about 7.89 inch).

38. The apparatus of claim 31, wherein said distance between the substrate and the side wall or the plate is from about 2 cm to about 10 cm (about 0.79 inch to about 3.94 inch).

39. The apparatus of claim 37, wherein the distribution conduit is disposed at a distance from about 0.5 cm to about 10 cm (about 0.15 inch to about 3.94 inch) from the substrate.

40. The apparatus of claim 38, wherein the distribution conduit is disposed at a distance from about 1.0 cm to about 5 cm (about 0.39 inch to about 1.97 inch) from the substrate.

41. The apparatus of claim 31, wherein each opening in the distributor conduit is spaced apart from another opening at a distance of about 0.1 cm to about 25 cm (about 0.04 inch to about 10 inch).

42. The apparatus of claim 31, wherein at least one of the length and the width of the substrate is greater than 30.48 cm (1 ft).

43. The apparatus of claim 31, wherein a surface area of the substrate is at least 0.185 m² (2 ft²).

44. The apparatus of claim 31, wherein at least one of the length and the width of the substrate is at least 121.92 cm (4 ft).

45. The apparatus of claim 31, wherein the distribution conduit is mounted in the processing chamber such that the entry port for the process gas or the activated reactive gas is disposed at a place of mounting.

46. The apparatus of claim 31, wherein the distribution conduit is mounted in the processing chamber such that the entry port for the process gas or the activated reactive gas is disposed substantially in a middle of the length of the distribution conduit.

47. A process for treatment of at least a portion of a surface of a substrate with an activated reactive gas, the process comprising:
providing a processing chamber, the processing chamber having an inner volume and an exhaust manifold disposed in the processing chamber;
providing a conveyor in communication with the processing chamber and the substrate;
placing the substrate having a length and a width in communication with the processing chamber and the conveyor, wherein the length of the substrate exceeds a dimension of the inner volume of the processing chamber;
providing a distribution conduit inside the processing chamber, the distribution conduit having a length and a plurality of openings, wherein the length of the distribution conduit is approximately equal to the width of the substrate, and wherein the distribution conduit has a number (N) of openings, each opening has a cross sectional area (Aₒ), and a cross sectional area of the distribution conduit (A_{c}), and wherein a maximum cross-sectional area (N*Aₒ) of the openings can be determined by the following expression:
1.0*A_{c}>N*Aₒ≧0.1*A_{c};
providing a supply of a process gas, the process gas comprising a reactive gas and optionally an additive gas;
providing an energy source in fluid communication with the processing chamber and the distribution conduit;
activating the process gas with the energy source to generate the activated reactive gas;
delivering the process gas or the activated reactive gas to the distribution conduit through the entry port;
removing a spent process gas via the exhaust manifold;
directing the process gas or the activated reactive gas from the distribution conduit onto the at least the portion of the surface of the substrate through the plurality of openings such that the process gas or the activated reactive gas is delivered uniformly along the width of the substrate;
sequentially presenting untreated portions of the substrate for said treatment in the processing chamber and sequentially removing from the processing chamber treated portions of the substrate; and
contacting the untreated portions of the substrate with the activated reactive gas and thereby providing said treatment.

48. The process of claim 47, wherein the energy source is selected from the group consisting of a remote plasma source, an in situ plasma source, and combinations thereof and optionally assisted by a remote thermal energy source, a catalytic energy source, an in-situ thermal energy source, electron attachment, a photon-based energy source, and combinations thereof.

49. The process of claim 47, wherein the energy source is a remote plasma source.

50. The process of claim 47, wherein the reactive gas comprises at least one of
(i) an oxygen-containing gas, wherein the oxygen-containing gas is a member selected from the group consisting of oxygen, ozone, nitric oxide, nitrous oxide, nitrogen dioxide, carbon monoxide, carbon dioxide, water, and mixtures thereof,
(ii) a fluorine-containing gas, wherein the fluorine-containing gas is a member selected from the group consisting of hydrofluoric acid, fluorine, fluoride, perfluorocarbon, hydrofluorocarbon, oxyfluorocarbon, oxygenated hydrofluorocarbon, hypofluorite, fluoroperoxide, dioxygen difluoride, fluorotrioxide, fluoroamine, fluoronitrile, and trifluoronitrosylmethane;
(iii) a chlorine-containing gas, wherein the chlorine-containing gas is a member selected from a group consisting of BCl₃, COCl₂, HCl, Cl₂, ClF₃, NFₓCl₃₋ₓ, where x is an integer ranging from 0 to 2, chlorocarbons, chlorohydrocarbons, and mixtures thereof.

51. The process of claim 50, wherein the fluorine-containing gas is a member selected from a group consisting of NF₃; SF₆; SF₄; SOF₂, SO₂F₂, COF₂, C₂F₂O₂, C₄F₈O, NOF, C₃F₃N₃, XeF₂, BrF₃, CF₄, C₂F₆, C₃F₈, C₄F₈, CHF₃, C₃F₇H, CH₃OCF₃, CF₃OF, FOCF₂OF, CF₃O₂CF₃, CF₃O₃CF₃, CF₅N, C₂F₃N, C₃F₆N, and mixtures thereof.

52. The process of claim 47, wherein the process gas comprises the additive gas.

53. The process of claim 52, wherein the additive gas is a member selected from the group consisting of H₂, N₂, He, Ne, Kr, Xe, Ar, and mixtures thereof.

54. The process of claim 47, wherein said directing of the process gas or the activated reactive gas through the plurality of openings of the distribution conduit is conducted in a direction substantially perpendicular to the surface of the substrate during said treatment and wherein the distribution conduit is arranged to be substantially parallel to the surface of the substrate.

55. The process of claim 47, wherein the substrate comprises glass.

56. The process of claim 47, wherein said contacting is conducted at a pressure below 760 torr (101.3 kPa).

57. The process of claim 47, wherein the treatment is at least one of oxidation, reduction, nitriding, carburization, halogenation, roughening, smoothening, cleaning, or etching.

58. The process of claim 47, wherein the treatment excludes layer depositions.

59. A process for treatment of at least a portion of a surface of a substrate with an activated reactive gas, the process comprising:
providing a processing chamber, the processing chamber having an inner volume and an exhaust manifold disposed in the processing chamber;
providing a conveyor in communication with the processing chamber and the substrate;
placing the substrate having a length and a width in communication with the processing chamber and the conveyor, wherein the length of the substrate exceeds a dimension of the inner volume of the processing chamber;
providing a distribution conduit inside the processing chamber, the distribution conduit having a length, an entry port for the process gas or the activated reactive gas, and a plurality of openings for directing a process gas or the activated reactive gas into the inner volume, wherein the length of the distribution conduit is approximately equal to the width of the substrate, and wherein each opening of the distribution conduit has a sidewall chamfered at an angle (α), each opening is spaced apart from another opening by a distance (x), and the distribution conduit is disposed at a distance (y) from the substrate presented for said treatment such that
x/(2*tan α)≦y;
providing a supply of a process gas, the process gas comprising a reactive gas and optionally an additive gas;
providing an energy source in fluid communication with the processing chamber and the distribution conduit;
activating the process gas with the energy source to generate the activated reactive gas;
delivering the process gas or the activated reactive gas to the distribution conduit through the entry port;
removing a spent process gas via the exhaust manifold;
directing the process gas or the activated reactive gas from the distribution conduit onto the at least the portion of the surface of the substrate through the plurality of openings such that the process gas or the activated reactive gas is delivered uniformly along the width of the substrate;
sequentially presenting untreated portions of the substrate for said treatment in the processing chamber and sequentially removing from the processing chamber treated portions of the substrate; and
contacting the untreated portions of the substrate with the activated reactive gas and thereby providing said treatment.

60. A process for treatment of a substrate with an activated reactive gas, the apparatus comprising:
providing a processing chamber, the processing chamber having an inner volume, a side wall, an exhaust manifold and optionally a plate, the plate being disposed between the side wall of the processing chamber and the substrate;
placing the substrate inside the processing chamber and in front of the side wall or the plate such that a distance between the substrate and the side wall or the substrate and the plate is selected to allow a uniform contact of the activated reactive gas with a surface of the substrate, the substrate having a length and a width;
providing a distribution conduit inside the processing chamber, wherein the distribution conduit is provided in at least one of the following configurations: (i) between the substrate and the side wall of the processing chamber or (ii) between the substrate and the plate, such that the distribution conduit is disposed substantially parallel to the surface of the substrate, the distribution conduit having a length, an entry port for the process gas or the activated reactive gas and a plurality of openings for directing a process gas or the activated reactive gas into the inner volume, wherein said length is approximately equal to at least one of the length and the width of the substrate;
providing a supply of a process gas, the process gas comprising a reactive gas and optionally an additive gas;
providing an energy source for activating the process gas in fluid communication with the processing chamber and the distribution conduit;
activating the process gas with the energy source to generate the activated reactive gas;
delivering the process gas or the activated reactive gas to the distribution conduit through the entry port;
removing a spent process gas via the exhaust manifold;
directing the process gas or the activated reactive gas from the distribution conduit onto the surface of the substrate through the openings of the distribution conduit such that the process gas is delivered uniformly along the width or the length of the substrate in a direction substantially parallel to the surface of the substrate;
contacting the surface of the substrate with the activated reactive gas and thereby providing said treatment.

61. The process of claim 60, wherein the energy source is selected from the group consisting of a remote plasma source, an in situ plasma source, and combinations thereof and optionally assisted by a remote thermal energy source, a catalytic energy source, an in-situ thermal energy source, electron attachment, a photon-based energy source, and combinations thereof.

62. The process of claim 60, wherein the energy source is a remote plasma source.

63. The process of claim 60, wherein the treatment is at least one of oxidation, reduction, nitriding, carburization, halogenation, roughening, smoothening, cleaning, or etching.

64. The process of claim 60, wherein the treatment excludes layer depositions.

65. The process of claim 60, wherein the distribution conduit has a number (N) of openings, each opening has a cross sectional area (Aₒ), and a cross sectional area of the distribution conduit (A_{c}), and wherein a maximum cross-sectional area (N*Aₒ) of the openings can be determined by the following expression:
1.0*A_{c}A_{c}>N*Aₒ≧0.1*A_{c}.

66. The process of claim 60, wherein said distance between the substrate and the side wall or the plate is from about 1 cm to about 20 cm (about 0.39 inch to about 7.89 inch).

67. The process of claim 66, wherein said distance between the substrate and the side wall or the plate is from about 2 cm to about 10 cm (about 0.79 inch to about 3.94 inch).
